(19) United States
(12) Patent Application Publication
(10) Pub. No.: US 2026/0007043 A1
(43) Pub. Date: Jan. 1, 2026

(54) DISPLAY APPARATUS AND ELECTRONIC DEVICE INCLUDING THE SAME

(71) Applicant: Samsung Display Co., Ltd., Yongin-si (KR)

(72) Inventors: Soohong Cheon, Yongin-si (KR); Kyeuk Lee, Yongin-si (KR)

(21) Appl. No.: 19/249,889

(22) Filed: Jun. 25, 2025

(30) Foreign Application Priority Data
Jun. 26, 2024 (KR) 10-2024-0083935
Feb. 18, 2025 (KR) 10-2025-0020964

(51) Int. Cl. H10K 59/80; H10K 59/38

(52) U.S. Cl. CPC H10K 59/8722; H10K 59/38; H10K 59/873

(57) ABSTRACT

A display apparatus includes a lower panel including a display area and a non-display area outside the display area, the lower panel including a light-emitting element in the display area and an encapsulation layer covering the light-emitting element, an upper panel on the lower panel, a sealing member in the non-display area and located between the lower panel and the upper panel, and an outer structure in at least one of the lower panel and the upper panel and located outside an end of the encapsulation layer.

### CROSS-REFERENCE TO RELATED APPLICATION

This application claims priority to and the benefit of Korean Patent Application No. 10-2024-0083935, filed on Jun. 26, 2024, and Korean Patent Application No 10-2025-0020964, filed on Feb. 18, 2025, in the Korean Intellectual Property Office, the entire disclosures of which are incorporated by reference herein.

### BACKGROUND

### 1. Field

One or more embodiments relate to a display apparatus and the structure of an electronic device including the display apparatus.

### 2. Description of the Related Art

Display apparatuses have a plurality of pixels. In order to implement a full-color display apparatus, pixels may emit light of different colors. To this end, at least some pixels of the display apparatus have a color conversion portion. Accordingly, a wavelength of light belonging to a first wavelength band, generated in a light-emitting portion of some pixels, is converted, while passing through a corresponding color conversion portion, into a wavelength of light belonging to a second wavelength band and emitted to the outside.

### SUMMARY

One or more embodiments include a display apparatus that prevents excessive pressing between a first substrate and a second substrate, thereby preventing moisture penetration and enhancing reliability, and an electronic device including the display apparatus. Embodiments set forth herein are examples, and the spirit and scope of the present disclosure is not limited thereby.

Additional aspects will be set forth in part in the description which follows and, in part, will be apparent from the description, or may be learned by practice of embodiments of the present disclosure.

According to one or more embodiments, a display apparatus includes a lower panel including a display area and a non-display area outside the display area, the lower panel including a light-emitting element in the display area and an encapsulation layer covering the light-emitting element, an upper panel on the lower panel, a sealing member in the non-display area and located between the lower panel and the upper panel, and an outer structure in at least one of the lower panel or the upper panel and located outside an end of the encapsulation layer.

A thickness of the outer structure may be less than a thickness of the sealing member based on a direction perpendicular to the lower panel.

The outer structure may have a dot shape in a plan view.

The outer structure may be located outside the sealing member.

The outer structure includes a plurality of outer structures, the plurality of outer structures being spaced from each other and being around the sealing member in a plan view.

The outer structure may be located between the end of the encapsulation layer and the sealing member.

The outer structure includes a plurality of outer structures, the plurality of outer structures being spaced from each other and being around the end of the encapsulation layer in a plan view.

The outer structure may include a first sub-outer structure and a second sub-outer structure that are spaced apart from each other, wherein the first sub-outer structure may be located outside the second sub-outer structure.

The outer structure may be located in the upper panel and may include a same material as a thickest layer among a plurality of layers located in the upper panel.

The upper panel may further include a light conversion portion that is configured to convert light emitted from the light-emitting element, and the outer structure may include a same material as a bank layer in the light conversion portion.

The upper panel may further include an upper substrate, a color filter layer located on a lower surface of the upper substrate in the non-display area, and a column spacer on a lower surface of the color filter layer in the non-display area, wherein the outer structure may be on a lower surface of the color filter and may be located outside the column spacer.

The upper panel may further include an upper substrate, a color filter layer located on a lower surface of the upper substrate in the non-display area, and a column spacer on a lower surface of the color filter layer in the non-display area, wherein the outer structure may be located on the lower surface of the color filter and may be located inside the column spacer.

The outer structure may include a same material as a green color filter located in the upper panel.

The upper panel may further include an upper substrate, a color filter layer located on a lower surface of the upper substrate in the non-display area and including a red color filter and a blue color filter, and a column spacer on a lower surface of the color filter layer in the non-display area, wherein the outer structure may be located on the lower surface of the color filter layer and may be located outside the column spacer.

The upper panel may further include an upper substrate, a color filter layer located on a lower surface of the upper substrate in the non-display area and including a red color filter and a blue color filter, and a column spacer on a lower surface of the color filter layer in the non-display area, wherein the outer structure may be located on the lower surface of the color filter layer and may be located inside the column spacer.

The lower panel may further include a light conversion portion located between the light-emitting element and the upper panel.

The outer structure may include a same material as a column spacer located in the upper panel.

The upper panel may further include an upper substrate, and a color filter layer located on a lower surface of the upper substrate in the non-display area, wherein the outer structure may be on a lower surface of the color filter layer.

The lower panel may further include a light conversion portion located between the light-emitting element and the upper panel.

The outer structure may be located in the lower panel and may include a same material as a thickest layer from among a plurality of layers located in the lower panel.

The lower panel may further include a light conversion portion that is configured to convert light emitted from the light-emitting element, and the outer structure may include a same material as a bank layer included in the light conversion portion.

The outer structure may include a lower outer structure located in the lower panel, and an upper outer structure located in the upper panel.

The lower panel may further include a light conversion portion that is configured to convert light emitted from the light-emitting element, and the outer structure may include a same material as a bank layer included in the light conversion portion.

The upper outer structure may include a same material as a column spacer or a green color filter located in the upper panel.

According to one or more embodiments, a display apparatus includes a first substrate including a display area and a non-display area outside the display area, a light-emitting element in the display area and located on the first substrate, an encapsulation layer covering the light-emitting element, a second substrate located above the first substrate with the light-emitting element and the encapsulation layer therebetween, a sealing member in the non-display area and located between the first substrate and the second substrate, and an outer structure located outside an end of the encapsulation layer.

The outer structure may be on at least one of an upper surface of the first substrate or a lower surface of the second substrate.

The outer structure may be located outside the sealing member. layer and the sealing member.

The outer structure may be located between the end of the encapsulation

The outer structure located on a lower surface of the second substrate may include a same material as a thickest layer from among a plurality of layers formed on the lower surface of the second substrate.

The display apparatus may further include a light conversion portion located on a lower surface of the second substrate and configured to convert light emitted from the light-emitting element, wherein the outer structure may be located on the lower surface of the second substrate and may include a same material as a bank layer included in the light conversion portion.

The display apparatus may further include a color filter layer located on a lower surface of the second substrate and configured to allow only some of light emitted from the light-emitting element to pass through, wherein the outer structure may be located on the lower surface of the second substrate and may include a same material as a green color filter in the color filter layer.

The display apparatus may further include a column spacer located on a lower surface of the second substrate and separating the first substrate from the second substrate, wherein the outer structure may be located on the lower surface of the second substrate and may include a same material as the column spacer.

The outer structure located on an upper surface of the first substrate may include a same material as a thickest layer from among a plurality of layers on the upper surface of the first substrate.

The display apparatus may further include a light conversion portion located on an upper surface of the first substrate and configured to convert light emitted from the light-emitting element, wherein the outer structure may be located on the upper surface of the first substrate and may include a same material as a bank layer in the light conversion portion.

The outer structure may further include a lower outer structure located on an upper surface of the first substrate, and an upper outer structure located on a lower surface of the second substrate.

The display apparatus may further include a light conversion portion located on the upper surface of the first substrate and configured to convert light emitted from the light-emitting element, a color filter layer located on the lower surface of the second substrate and configured to allow only some of light emitted from the light-emitting element to pass through, and a column spacer located on the lower surface of the second substrate and separating the first substrate from the second substrate, wherein the lower outer structure may include a same material as a bank layer in the light conversion portion, and the upper outer structure may include a same material as a green color filter of the color filter layer, or the column spacer.

According to one or more embodiments, an electronic device includes a display apparatus configured to display an image, and a housing in which the display apparatus is located, wherein the display apparatus includes a lower panel including a display area and a non-display area outside the display area, the lower panel including a light-emitting element located in the display area and an encapsulation layer covering the light-emitting element, an upper panel on the lower panel, a sealing member in the non-display area and located between the lower panel and the upper panel, and an outer structure in at least one of the lower panel or the upper panel and located outside an end of the encapsulation layer.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a schematic perspective view of a display apparatus according to one or more embodiments;

FIG. 2 is a schematic cross-sectional view of a display apparatus according to one or more embodiments;

FIG. 3 is an equivalent circuit diagram of a pixel provided in a display apparatus according to one or more embodiments;

FIG. 4 is a cross-sectional view of the display apparatus taken along the line A-A′ of FIG. 1;

FIG. 5 is a cross-sectional view of the display apparatus taken along the line B-B′ of FIG. 1;

FIG. 6 is a schematic plan view of a display apparatus according to one or more embodiments;

FIG. 7 is a schematic cross-sectional view of a display apparatus according to one or more embodiments;

FIG. 8 is a schematic cross-sectional view of a display apparatus according to one or more embodiments;

FIG. 9 is a schematic cross-sectional view of a display apparatus according to one or more embodiments;

FIG. 10 is a schematic cross-sectional view of a display apparatus according to one or more embodiments;

FIG. 11 is a schematic cross-sectional view of a display apparatus according to one or more embodiments;

FIG. 12 is a schematic cross-sectional view of a display apparatus according to one or more embodiments;

FIG. 13 is a schematic plan view of a display apparatus according to one or more embodiments;

FIG. 14 is a schematic cross-sectional view of a display apparatus according to one or more embodiments;

FIG. 15 is a block diagram of an electronic device according to one or more embodiments; and

FIG. 16 is a schematic diagram of electronic devices according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects and features of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

The present disclosure is subject to various modifications and may have many embodiments, certain of which are illustrated in the drawings and further described in the detailed description. The effects, aspects, and features of the present disclosure, and methods of achieving them will become clear with reference to the embodiments described below in detail together with the drawings. However, the present disclosure is not limited to the embodiments described herein and may be implemented in various forms.

Hereinafter, embodiments will be described in detail with reference to the accompanying drawings, and when being described with reference to the drawings, the same or corresponding components are given the same reference numerals, and duplicate descriptions thereof will be omitted.

In the following embodiments, the terms first, second, etc. are not intended to be limiting, however are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is the to be over or on top of another portion, this includes not only when it is directly on top of the other portion, but also when there are other films, areas, components, etc. arranged therebetween.

In the drawings, components may be exaggerated or reduced in size for ease of illustration. For example, the size and thickness of each configuration shown in the drawings are arbitrary for purposes of illustration and the present disclosure is not necessarily limited to those shown.

In one or more embodiments, a particular sequence of processes may be performed in a different order than that described. For example, two processes described in succession may be performed substantially concurrently (e.g., simultaneously), or may be performed in the opposite order from the order described.

In the present specification, the expression such as “A and/or B” may include A, B, or A and B. In the present specification, the expression such as “A and/or B” may include A, B, or A and B.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the following embodiments, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the following embodiments, the terms x-axis, y-axis, and z-axis are not limited to, however may be interpreted in a broad sense to include three axes in a Cartesian coordinate system. For example, the x-axis, y-axis, and z-axis may be orthogonal to each other, however, may also refer to different directions that are not orthogonal to each other.

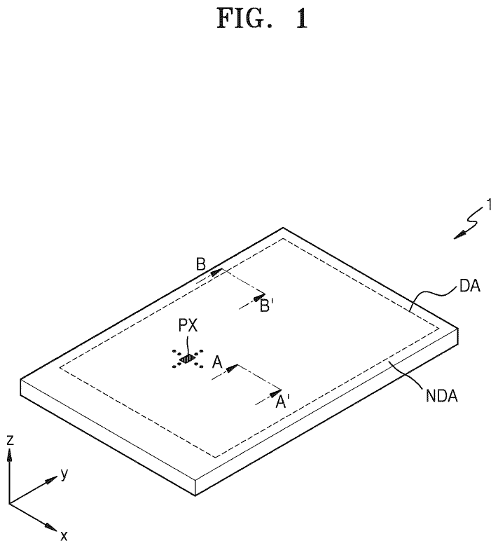

FIG. 1 is a schematic perspective view of a display apparatus 1 according to one or more embodiments.

Referring to FIG. 1, the display apparatus 1 may include a display area DA that displays an image and a non-display area NDA that does not display an image. The display apparatus 1 may provide an image to the outside by using light emitted from the display area DA.

Although FIG. 1 illustrates the display apparatus 1 in which the display area DA is a square or a rectangle, in another embodiments, the display area DA may be a circle, an ellipse, or a polygon, such as a triangle or a pentagon. In addition, although it is illustrated in FIG. 1 that the display apparatus 1 is a flat-panel display apparatus, the display apparatus 1 may be implemented in various forms, such as a flexible, foldable, and/or rollable display apparatus.

In one or more embodiments, the display apparatus 1 may be an organic light-emitting display apparatus. In another embodiment, the display apparatus 1 may be an inorganic light-emitting display apparatus or a quantum dot light-emitting display apparatus. For example, an emission layer of a display element included in the display apparatus 1 may include an organic material, an inorganic material, quantum dots, an organic material and quantum dots, an inorganic material and quantum dots, or an organic material, an inorganic material, and quantum dots. For convenience of explanation, the following description will focus on the case where the display apparatus 1 is an organic light-emitting display apparatus.

A plurality of pixels PX may be arranged in the display area DA. In the present specification, the pixels PX may refer to sub-pixels that emit different colors, and each of the pixels PX may be, for example, one of a red sub-pixel, a green sub-pixel, and a blue sub-pixel.

The non-display area NDA may be an area where no pixels PX are arranged, and power supply wiring and/or the like for driving the pixels PX may be located in the non-display area NDA. In addition, a printed circuit board (PCB) including a driving circuit portion or a terminal portion to which a driver integrated circuit (IC) is connected may be arranged in the non-display area NDA. The driving circuit portion may be placed in the non-display area NDA.

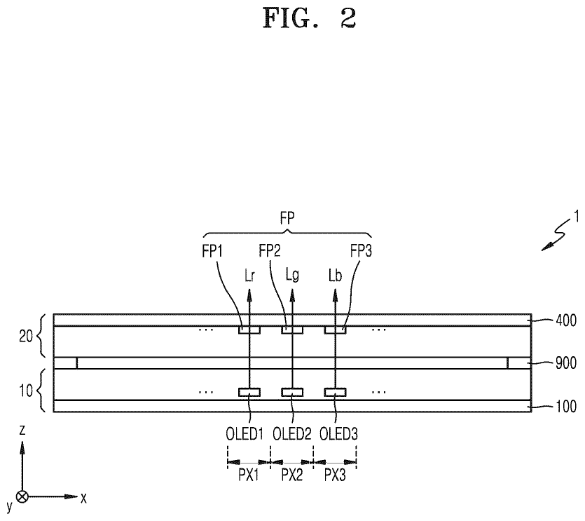

FIG. 2 is a schematic cross-sectional view of a display apparatus 1 according to one or more embodiments.

Referring to FIG. 2, the display apparatus 1 may include a first pixel PX1, a second pixel PX2, and a third pixel PX3. The first pixel PX1, the second pixel PX2, and the third pixel PX3 may be pixels that emit different colors. For example, the first pixel PX1 may emit red light Lr, the second pixel PX2 may emit green light Lg, and the third pixel PX3 may emit blue light Lb. In one or more embodiments, the display apparatus 1 may include a lower panel 10 and an upper panel 20. The lower panel 10 may include a first substrate 100 and a light-emitting element. The light-emitting element may be, for example, an organic light-emitting diode (OLED). In one or more embodiments, the first pixel PX1, the second pixel PX2, and the third pixel PX3 may each include an organic light-emitting diode (OLED). For example, the first pixel PX1 may include a first organic light-emitting diode OLED1. The second pixel PX2 may include a second organic light-emitting diode OLED2. The third pixel PX3 may include a third organic light-emitting diode OLED3.

In one or more embodiments, the first organic light-emitting diode OLED1, the second organic light-emitting diode OLED2, and the third organic light-emitting diode OLED3 may emit blue light. In another embodiment, the first organic light-emitting diode OLED1, the second organic light-emitting diode OLED2, and the third organic light-emitting diode OLED3 may emit the red light Lr, the green light Lg, and the blue light Lb, respectively.

The upper panel 20 may include a second substrate 400 and a filter portion FP. In one or more embodiments, the filter portion FP may include a first filter portion FP1, a second filter portion FP2, and a third filter portion FP3. Light emitted from the first organic light-emitting diode OLED1 may pass through the first filter portion FP1 and may be emitted as the red light Lr. Light emitted from the second organic light-emitting diode OLED2 may pass through the second filter portion FP2 and may be emitted as the green light Lg. Light emitted from the third organic light-emitting diode OLED3 may pass through the third filter portion FP3 and may be emitted as the blue light Lb.

In one or more embodiments, the filter portion FP may include a light conversion portion and a color filter layer. In one or more embodiments, a functional layer included in the light conversion portion may include a first quantum dot layer, a second quantum dot layer, and a transmissive layer. In one or more embodiments, the color filter layer may include a first color filter, a second color filter, and a third color filter. The first filter portion FP1 may include the first quantum dot layer and the first color filter. The second filter portion FP2 may include the second quantum dot layer and the second color filter. The third filter portion FP3 may include the transmissive layer and the third color filter.

The filter portion FP may be located directly on the second substrate 400. In this case, ‘located directly on the second substrate 400’ may mean that the first color filter, the second color filter, and the third color filter are formed directly on the second substrate 400 to manufacture the upper panel 20. That is, the filter portion FP may be placed on the lower surface of the second substrate 400. Thereafter, the upper panel 20 may be bonded to the lower panel 10 so that the first filter portion FP1, the second filter portion FP2, and the third filter portion FP3 face the first organic light-emitting diode OLED1, the second organic light-emitting diode OLED2, and the third organic light-emitting diode OLED3, respectively.

The lower panel 10 and the upper panel 20 may be connected to each other through a sealing member 900. In this case, the sealing member 900 may be placed to be around (e.g., to surround) the display area DA of the lower panel 10. For example, the sealing member 900 may be placed on the outer side of the display area DA in a plan view and may form a closed loop. In this case, the sealing member 900 and the upper panel 20 may completely block the display area DA from the outside. The sealing member 900 as described above may include a sealant, a frit, etc.

In one or more embodiments, a filler may be placed between the lower panel 10 and the upper panel 20.

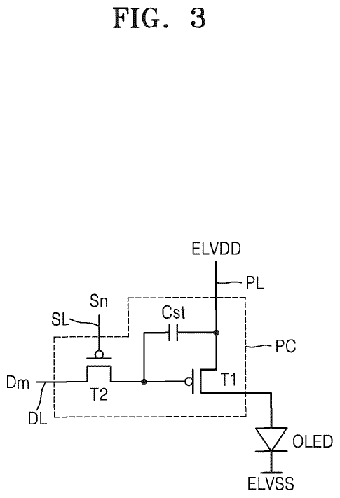

FIG. 3 is an equivalent circuit diagram of a pixel provided in a display apparatus according to one or more embodiments.

Referring to FIG. 3, each pixel may be implemented by a pixel circuit PC connected to a scan line SL and a data line DL and an organic light-emitting diode OLED connected to the pixel circuit PC. The pixel circuit PC may include a driving thin-film transistor T1, a switching thin-film transistor T2, and a storage capacitor Cst. The switching thin-film transistor T2 may be connected to the scan line SL and the data line DL and may be configured to transmit a data signal Dm, input through the data line DL, to the driving thin-film transistor T1 according to the scan signal Sn input through the scan line SL.

The storage capacitor Cst may be connected to the switching thin-film transistor T2 and a driving voltage line PL, and may store a voltage corresponding to a difference between a voltage transmitted from the switching thin-film transistor T2 and a first power voltage (e.g., a driving voltage) ELVDD supplied to the driving voltage line PL.

The driving thin-film transistor T1 may be connected to the driving voltage line PL and the storage capacitor Cst, and may be configured to control a driving current flowing through the organic light-emitting diode OLED from the driving voltage line PL in response to a voltage value stored in the storage capacitor Cst. The organic light-emitting diode OLED may emit light having a certain brightness via the driving current.

In FIG. 3, the case where the pixel circuit PC includes two thin-film transistors and one storage capacitor is illustrated. However, the present disclosure is not limited thereto, and the number of thin-film transistors and storage capacitor and the circuit design of the pixel circuit PC may be variously changed.

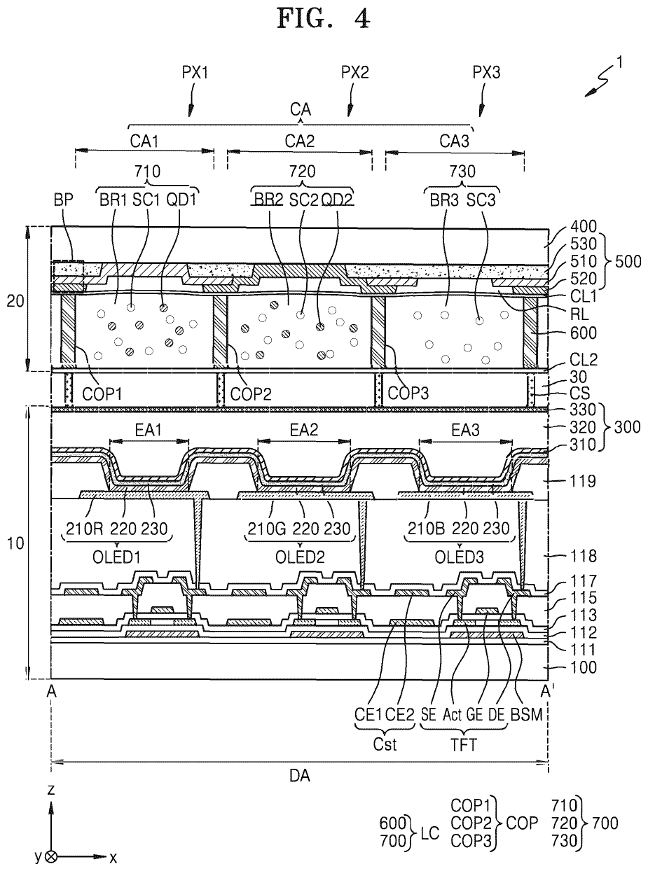

FIG. 4 is a cross-sectional view of the display apparatus 1 taken along the line A-A′ of FIG. 1.

Referring to FIG. 4, the display apparatus 1 may include a first pixel PX1, a second pixel PX2, and a third pixel PX3 arranged on a display area DA. This is an example, and the display apparatus 1 may include more pixels. Although FIG. 4 illustrates that the first pixel PX1, the second pixel PX2, and the third pixel PX3 are adjacent to each other, in another embodiment, the first pixel PX1, the second pixel PX2, and the third pixel PX3 may not be adjacent pixels.

The first pixel PX1, the second pixel PX2, and the third pixel PX3 may implement different lights. For example, the first pixel PX1 may implement red light, the second pixel PX2 may implement green light, and the third pixel PX3 may implement blue light.

In one or more embodiments, the display apparatus 1 may include a lower panel 10 and an upper panel 20. The lower panel 10 may include a first substrate 100 and a light-emitting element arranged on the first substrate 100. The light-emitting element may include an emission layer 220. In one or more embodiments, the lower panel 10 may include a first organic light-emitting diode OLED1, a second organic light-emitting diode OLED2, and a third organic light-emitting diode OLED3 arranged on the first substrate 100. The first organic light-emitting diode OLED1, the second organic light-emitting diode OLED2, and the third organic light-emitting diode OLED3 may commonly include the emission layer 220.

The stacked structure of the lower panel 10 will be described in detail below.

The first substrate 100 may include a glass material, a ceramic material, a metal material, and/or a material that is flexible and/or bendable. When the first substrate 100 is flexible or bendable, the first substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The first substrate 100 may have a single-layer or multi-layer structure including the aforementioned material, and in the case of a multi-layer structure, the first substrate 100 may further include an inorganic layer. In one or more embodiments, the first substrate 100 may have a structure including organic/inorganic/organic material layers.

A barrier layer may be further included between the first substrate 100 and a first buffer layer 111. The barrier layer may prevent or reduce impurities from the first substrate 100 and/or the like from penetrating into a semiconductor layer Act. The barrier layer may include an inorganic material such as an oxide and/or a nitride, an organic material, or an organic-inorganic composite, and may have a single-layer or multi-layer structure including an inorganic material and an organic material.

A bias electrode BSM may be arranged on the first buffer layer 111 to correspond to a thin-film transistor TFT. In one or more embodiments, a voltage may be applied to the bias electrode BSM. In addition, the bias electrode BSM may prevent external light from reaching the semiconductor layer Act. Accordingly, the characteristics of the thin-film transistor TFT may be stabilized. The bias electrode BSM may be omitted in some cases.

The semiconductor layer Act may be arranged on a second buffer layer 112 on the first buffer layer 111 and the bias electrode BSM. The semiconductor layer Act may include amorphous silicon or polysilicon. In one or more embodiments, the semiconductor layer Act may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In one or more embodiments, the semiconductor layer Act may include a Zn oxide-based material, such as Zn oxide, In—Zn oxide, or Ga—In—Zn oxide. In one or more embodiments, the semiconductor layer Act may include an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn), in ZnO. The semiconductor layer Act may include a channel region and a source region and a drain region arranged on both sides of the channel region. The semiconductor layer Act may include a single layer or multiple layers.

A gate electrode GE may be arranged on the semiconductor layer Act with a gate insulating layer 113 therebetween. The gate electrode GE may at least partially overlap the semiconductor layer Act. The gate electrode GE may include molybdenum (Mo), aluminum (Al), copper (Cu), titanium (Ti), and/or the like, and may include a single layer or multiple layers. As an example, the gate electrode GE may include a single layer of Mo. A first electrode CE1 of a storage capacitor Cst may be arranged on (e.g., at) the same layer as the gate electrode GE. The first electrode CE1 may include the same material as the gate electrode GE.

In FIG. 4, the gate electrode GE of the thin-film transistor TFT and the first electrode CE1 of the storage capacitor Cst are separately arranged. However, the storage capacitor Cst may overlap the thin-film transistor TFT. In this case, the gate electrode GE of the thin-film transistor TFT may function as the first electrode CE1 of the storage capacitor Cst.

An interlayer insulating layer 115 may be provided on the gate insulating layer 113 to cover the gate electrode GE and the first electrode CE1 of the storage capacitor Cst. The interlayer insulating layer 115 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO), and/or the like.

A second electrode CE2 of the storage capacitor Cst, a source electrode SE, a drain electrode DE, and/or the like may be arranged on the interlayer insulating layer 115.

The second electrode CE2 of the storage capacitor Cst, the source electrode SE, and the drain electrode DE may each include a conductive material including molybdenum (Mo), aluminum (Al), copper (Cu), titanium (Ti), and/or the like, and may include a multilayer or single layer including the aforementioned material. For example, the second electrode CE2, the source electrode SE, and the drain electrode DE may have a multi-layer structure including Ti/Al/Ti layers. The source electrode SE and the drain electrode DE may each be connected to the source region or the drain region of the semiconductor layer Act through a contact hole.

The second electrode CE2 of the storage capacitor Cst may overlap the first electrode CE1 with the interlayer insulating layer 115 therebetween and may form the storage capacitor Cst. In this case, the interlayer insulating layer 115 may function as a dielectric layer of the storage capacitor Cst.

A wiring protection layer 117 may be arranged on the interlayer insulating layer 115 to cover the second electrode CE2 of the storage capacitor Cst, the source electrode SE, and the drain electrode DE. In this case, the wiring protection layer 117 may include an inorganic insulating material, such as silicon nitride, silicon oxide, and/or silicon oxynitride. The wiring protection layer 117 may prevent wiring including a metal (e.g., copper, etc.), which may be damaged by an etchant during the process of manufacturing the display apparatus 1, from being exposed to an etching environment.

A planarization layer 118 may be arranged on the wiring protection layer 117. The planarization layer 118 may be formed as a single layer or multilayer of a film including an organic material and may provide a flat upper surface. The planarization layer 118 may include a general-purpose polymer, such as benzocyclobutene (BCB), polyimide, hexamethyldisiloxane (HMDSO), polymethylmethacrylate (PMMA), and/or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, and/or the like.

A display element may be arranged on the planarization layer 118. In one or more embodiments, the first organic light-emitting diode OLED1, the second organic light-emitting diode OLED2, and the third organic light-emitting diode OLED3 may be arranged on the planarization layer 118. The first organic light-emitting diode OLED1, the second organic light-emitting diode OLED2, and the third organic light-emitting diode OLED3 may include a first pixel electrode 210R, a second pixel electrode 210G, and a third pixel electrode 210B, respectively. In one or more embodiments, the first organic light-emitting diode OLED1, the second organic light-emitting diode OLED2, and the third organic light-emitting diode OLED3 may commonly include an emission layer 220 and an opposite electrode 230.

The first pixel electrode 210R, the second pixel electrode 210G, and the third pixel electrode 210B may be (semi-)light-transmitting electrodes or reflective electrodes. In one or more embodiments, the first pixel electrode 210R, the second pixel electrode 210G, and the third pixel electrode 210B may each include a reflective layer including Ag, Mg, Al, Pt, Pd, Au, Ni, Nd, Ir, Cr, or a compound thereof, and a transparent or semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In one or more embodiments, the first pixel electrode 210R, the second pixel electrode 210G, and the third pixel electrode 210B may each include ITO/Ag/ITO layers.

A pixel-defining layer 119 may be arranged on the planarization layer 118. The pixel-defining layer 119 may have openings that expose central portions of the first pixel electrode 210R, the second pixel electrode 210G, and the third pixel electrode 210B, respectively. The pixel-defining layer 119 may cover the edge of each of the first pixel electrode 210R, the second pixel electrode 210G, and the third pixel electrode 210B. The pixel-defining layer 119 may prevent arcs and/or the like from occurring at the edges of the first pixel electrode 210R, the second pixel electrode 210G, and the third pixel electrode 210B by increasing the distance between the edges of the first pixel electrode 210R, the second pixel electrode 210G, and the third pixel electrode 210B and the opposite electrode 230 above the first pixel electrode 210R, the second pixel electrode 210G, and the third pixel electrode 210B.

The pixel-defining layer 119 may be formed by a method, such as spin coating and may include one or more organic insulating materials selected from the group consisting of polyimide, polyamide, acrylic resin, benzocyclobutene, and phenol resin.

The emission layer 220 commonly included in the first organic light-emitting diode OLED1, the second organic light-emitting diode OLED2, and the third organic light-emitting diode OLED3 may include an organic material including a fluorescent or phosphorescent material that emits red, green, blue, or white light. The emission layer 220 may include a low-molecular organic material or a high-molecular organic material, and functional layers, such as a hole transport layer (HTL), a hole injection layer (HIL), an electron transport layer (ETL), and an electron injection layer (EIL), may be selectively further arranged below and above the emission layer 220. FIG. 4 illustrates an example in which the emission layer 220 is integrally formed as a single body over the first pixel electrode 210R, the second pixel electrode 210G, and the third pixel electrode 210B. However, the present disclosure is not limited thereto and various modifications may be made. For example, the emission layer 220 may be arranged to correspond to each of the first pixel electrode 210R, the second pixel electrode 210G, and the third pixel electrode 210B.

As described above, the emission layer 220 may include an integral layer over the first pixel electrode 210R, the second pixel electrode 210G, and the third pixel electrode 210B, but may also include a layer patterned to correspond to each of the first pixel electrode 210R, the second pixel electrode 210G, and the third pixel electrode 210B, if necessary. In one or more embodiments, the emission layer 220 may be a first color emission layer. The first color emission layer may be integrally formed as a single body over the first pixel electrode 210R, the second pixel electrode 210G, and the third pixel electrode 210B, or, if necessary, the first color emission layer may be patterned to correspond to each of the first pixel electrode 210R, the second pixel electrode 210G, and the third pixel electrode 210B. The first color emission layer may emit light of a first wavelength band, for example, light of a wavelength ranging from about 450 nm to about 495 nm.

The opposite electrode 230 may be located on the emission layer 220 to correspond to the first pixel electrode 210R, the second pixel electrode 210G, and the third pixel electrode 210B. The opposite electrode 230 may be integrally formed as a single body in a plurality of organic light-emitting elements. In one or more embodiments, the opposite electrode 230 may be a transparent or semi-transparent electrode, and may include a metal thin film having a low work function and including Li, Ca, LiF/Ca, LiF/Al, Al, Ag, Mg, or a compound thereof. In addition, a transparent conductive oxide (TCO) film, such as an ITO, IZO, ZnO, or In₂O₃ film, may be further arranged on the metal thin film.

In one or more embodiments, first light may be generated in a first emission area EA1 of the first organic light-emitting diode OLED1 and emitted to the outside. The first emission area EA1 may be defined as a portion of the first pixel electrode 210R exposed by an opening in the pixel-defining layer 119. Second light may be generated in a second emission area EA2 of the second organic light-emitting diode OLED2 and emitted to the outside. The second emission area EA2 may be defined as a portion of the second pixel electrodes 210G exposed by an opening in the pixel-defining layer 119. Third light may be generated in a third emission area EA3 of the third organic light-emitting diode OLED3 and emitted to the outside. The third emission area EA3 may be defined as a portion of the third pixel electrodes 210B exposed by an opening of the pixel-defining layer 119.

The first emission area EA1, the second emission area EA2, and the third emission area EA3 may be spaced (e.g., spaced apart) from each other. An area of the display area DA other than the first emission area EA1, the second emission area EA2, and the third emission area EA3 may be a non-emission area. The first emission area EA1, the second emission area EA2, and the third emission area EA3 may be distinguished by the non-emission area. In a plan view, the first emission area EA1, the second emission area EA2, and the third emission area EA3 may be arranged in various arrangements, such as a stripe arrangement and/or a PENTILE® arrangement. PENTILE® is a registered trademark of Samsung Display Co., Ltd., Republic of Korea. In a plan view, the shape of the first emission area EA1, the shape of the second emission area EA2, and the shape of the third emission area EA3 may each be one of a polygon, a circle, or an ellipse.

A spacer for preventing mask imprinting may be further provided on the pixel-defining layer 119. The spacer may be formed integrally with the pixel-defining layer 119. For example, the spacer and the pixel-defining layer 119 may be concurrently (e.g., simultaneously) formed in the same process by using a halftone mask process.

Because the first organic light-emitting diode OLED1, the second organic light-emitting diode OLED2, and the third organic light-emitting diode OLED3 may be easily damaged by moisture and/or oxygen from the outside, they may be protected by being covered with an encapsulation layer 300. The encapsulation layer 300 may cover the display area DA and extend to the outside of the display area DA. The encapsulation layer 300 may include at least one organic encapsulation layer and at least one inorganic encapsulation layer. For example, the encapsulation layer 300 may include a first inorganic encapsulation layer 310, an organic encapsulation layer 320, and a second inorganic encapsulation layer 330.

Because the first inorganic encapsulation layer 310 is formed along the structure thereunder, the upper surface of the first inorganic encapsulation layer 310 may not be flat. The organic encapsulation layer 320 may cover the first inorganic encapsulation layer 310, and unlike the first inorganic encapsulation layer 310, the upper surface of the organic encapsulation layer 320 may be approximately flat.

The first inorganic encapsulation layer 310 and the second inorganic encapsulation layer 330 may each include one or more inorganic materials from among aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (SiN_{X}), and/or silicon oxynitride (SiON). The organic encapsulation layer 320 may include a polymer-based material. Examples of the polymer-based material may include an acrylic resin, an epoxy resin, polyimide, and/or polyethylene. In one or more embodiments, the organic encapsulation layer 320 may include an acrylate.

Even when a crack occurs within (e.g., in) the encapsulation layer 300 through the multi-layer structure described above, the encapsulation layer 300 may prevent the crack from being connected between the first inorganic encapsulation layer 310 and the organic encapsulation layer 320 or between the organic encapsulation layer 320 and the second inorganic encapsulation layer 330. Through this, the formation of a path through which moisture and/or oxygen from the outside may penetrate into the display area DA may be prevented or reduced.

In one or more embodiments, other layers such as a capping layer may be arranged between the first inorganic encapsulation layer 310 and the opposite electrode 230 as needed.

The upper panel 20 may include a second substrate 400, a color filter layer 500, a refractive layer RL, a first capping layer CL1, a light conversion portion LC, and a second capping layer CL2. The second substrate 400 may be arranged on the first substrate 100 so that a light-emitting element is interposed therebetween. The second substrate 400 may be arranged on the first organic light-emitting diode OLED1, the second organic light-emitting diode OLED2, and the third organic light-emitting diode OLED3.

The second substrate 400 may include a central area CA overlapping a display element. In one or more embodiments, the central area CA may include a first central area CA1, a second central area CA2, and a third central area CA3. The first central area CA1 may overlap the first organic light-emitting diode OLED1 and/or the first emission area EA1. The second central area CA2 may overlap the second organic light-emitting diode OLED2 and/or the second emission area EA2. The third central area CA3 may overlap the third organic light-emitting diode OLED3 and/or the third emission area EA3.

The second substrate 400 may include glass, metal, and/or polymer resin. When the second substrate 400 is flexible and/or bendable, the second substrate 400 may include a polymer resin, such as polyethersulphone, polyacrylate, polyetherimide, polyethylene naphthalate, polyethylene terephthalate, polyphenylene sulfide, polyarylate, polyimide, polycarbonate, and/or cellulose acetate propionate. In one or more embodiments, the second substrate 400 may have a multi-layer structure including two layers each including the polymer resin and a barrier layer including an inorganic material, such as silicon oxide (SiO₂), silicon nitride (SiN_{X}), and/or silicon oxynitride (SiON), arranged between the two layers.

The color filter layer 500 may be arranged on the lower surface of the second substrate 400 facing the first substrate 100 from the second substrate 400. The color filter layer 500 may include a first color filter 510, a second color filter 520, and a third color filter 530. The first color filter 510 may be arranged on the first central area CA1. The second color filter 520 may be arranged on the second central area CA2. The third color filter 530 may be arranged on the third central area CA3. The first color filter 510, the second color filter 520, and the third color filter 530 may each include a photosensitive resin material. The first color filter 510, the second color filter 520, and the third color filter 530 may each include a dye that represents a unique color. The first color filter 510 may allow only light having a wavelength of about 630 nm to about 780 nm to pass through, the second color filter 520 may allow only light having a wavelength of about 495 nm to about 570 nm to pass through, and the third color filter 530 may allow only light having a wavelength of about 450 nm to about 495 nm to pass through.

The color filter layer 500 may reduce external light reflection of the display apparatus 1. For example, when external light reaches the first color filter 510, only light having a suitable wavelength (e.g., a preset wavelength) as described above may pass through the first color filter 510, and light having a wavelength other than the suitable wavelength (e.g., the preset wavelength) may be absorbed by the first color filter 510. Therefore, of the external light incident on the display apparatus 1, only the light having the suitable wavelength (e.g., the preset wavelength) may pass through the first color filter 510, and some of the light may be reflected by the opposite electrode 230 and/or the first pixel electrode 210R under the first color filter 510, and then may be emitted to the outside again. The first color filter 510 may reduce the external light reflection by allowing only some of the external light incident on the location where the first pixel PX1 is located to be reflected to the outside. This description may also apply to the second color filter 520 and the third color filter 530.

The first color filter 510, the second color filter 520, and the third color filter 530 may overlap each other. The first color filter 510, the second color filter 520, and the third color filter 530 may overlap each other between one of the central areas CA and the other of the central areas CA. For example, the first color filter 510, the second color filter 520, and the third color filter 530 may overlap each other between the first central area CA1 and the second central area CA2. In this case, the third color filter 530 may be arranged between the first central area CA1 and the second central area CA2. The first color filter 510 may extend from the first central area CA1 and overlap the third color filter 530. The second color filter 520 may extend from the second central area CA2 and overlap the third color filter 530.

The first color filter 510, the second color filter 520, and the third color filter 530 may overlap each other between the second central area CA2 and the third central area CA3. The first color filter 510 may be arranged between the second central area CA2 and the third central area CA3. The second color filter 520 may extend from the second central area CA2 and overlap the first color filter 510. The third color filter 530 may extend from the third central area CA3 and overlap the first color filter 510.

The first color filter 510, the second color filter 520, and the third color filter 530 may overlap each other between the third central area CA3 and the first central area CA1. The second color filter 520 may be arranged between the third central area CA3 and the first central area CA1. The third color filter 530 may extend from the third central area CA3 and overlap the second color filter 520. The first color filter 510 may extend from the first central area CA1 and overlap the second color filter 520.

As described above, the first color filter 510, the second color filter 520, and the third color filter 530 may overlap each other to define a light-blocking portion BP. Therefore, the color filter layer 500 may prevent or reduce color mixing even without a separate light-blocking member.

The refractive layer RL may be arranged in the central area CA. The refractive layer RL may be arranged in each of the first central area CA1, the second central area CA2, and the third central area CA3. The refractive layer RL may include an organic material. In one or more embodiments, the refractive index of the refractive layer RL may be lower than the refractive index of the first capping layer CL1. In one or more embodiments, the refractive index of the refractive layer RL may be lower than the refractive index of the color filter layer 500. Therefore, the refractive layer RL can collect light.

The first capping layer CL1 may be arranged on the lower surfaces of the color filter layer 500 and the refractive layer RL. In one or more embodiments, the first capping layer CL1 may be arranged between the color filter layer 500 and the light conversion portion LC. The first capping layer CL1 may protect the refractive layer RL and the color filter layer 500. The first capping layer CL1 may prevent or reduce damage and/or contamination of the refractive layer RL and/or the color filter layer 500 by impurities, such as moisture and/or air, penetrating from the outside. The first capping layer CL1 may include an inorganic material.

The light conversion portion LC may include a bank layer 600 and a functional layer 700. The bank layer 600 may be arranged on the lower surface of the first capping layer CL1. The bank layer 600 may include an organic material. In some cases, the bank layer 600 may include a light-blocking material to function as a light-blocking layer. The light-blocking material may include, for example, a black pigment, a black dye, black particles, and/or metal particles.

A plurality of openings may be defined in the bank layer 600. For example, a central opening COP may be defined in the bank layer 600. The central opening COP may overlap the central area CA. In one or more embodiments, a plurality of central openings COP may overlap the central area CA. For example, a first central opening COP1 may overlap the first central area CA1. A second central opening COP2 may overlap the second central area CA2. A third central opening COP3 may overlap the third central area CA3.

The functional layer 700 may fill the central opening COP. In one or more embodiments, the functional layer 700 may include at least one of a quantum dot or a scatterer. In one or more embodiments, the functional layer 700 may include a first quantum dot layer 710, a second quantum dot layer 720, and a transmissive layer 730.

The first quantum dot layer 710 may overlap the first central area CA1. The first quantum dot layer 710 may fill the first central opening COP1. The first quantum dot layer 710 may overlap the first emission area EA1. The first pixel PX1 may include the first organic light-emitting diode OLED1 and the first quantum dot layer 710.

The first quantum dot layer 710 may convert light of a first wavelength band generated in the emission layer 220 on the first pixel electrode 210R into light of a second wavelength band. For example, when light having a wavelength of about 450 nm to about 495 nm is generated in the emission layer 220 on the first pixel electrode 210R, the first quantum dot layer 710 may convert the light into light having a wavelength of about 630 nm to about 780 nm. Accordingly, in the first pixel PX1, the light having a wavelength of about 630 nm to about 780 nm may be emitted to the outside through the second substrate 400. In one or more embodiments, the first quantum dot layer 710 may include a first quantum dot QD1, a first scatterer SC1, and a first base resin BR1. The first quantum dot QD1 and the first scatterer SC1 may be dispersed in the first base resin BR1.

The second quantum dot layer 720 may overlap the second central area CA2. The second quantum dot layer 720 may fill the second central opening COP2. The second quantum dot layer 720 may overlap the second emission area EA2. The second pixel PX2 may include the second organic light-emitting diode OLED2 and the second quantum dot layer 720.

The second quantum dot layer 720 may convert light of a first wavelength band generated in the emission layer 220 on the second pixel electrode 210G into light of a third wavelength band. For example, when light of a wavelength ranging from about 450 nm to about 495 nm is generated in the emission layer 220 on the second pixel electrode 210G, the second quantum dot layer 720 may convert the light into light having a wavelength ranging from about 495 nm to about 570 nm. Therefore, in the second pixel PX2, the light having a wavelength ranging from about 495 nm to about 570 nm may be emitted to the outside through the second substrate 400. In one or more embodiments, the second quantum dot layer 720 may include a second quantum dot QD2, a second scatterer SC2, and a second base resin BR2. The second quantum dot QD2 and the second scatterer SC2 may be dispersed in the second base resin BR2.

The transmissive layer 730 may overlap the third central area CA3. The transmissive layer 730 may fill the third central opening COP3. The transmissive layer 730 may overlap the third emission area EA3. The third pixel PX3 may include the third organic light-emitting diode OLED3 and the transmissive layer 730.

The transmissive layer 730 may emit light generated in the emission layer 220 on the third pixel electrode 210B to the outside without wavelength conversion. For example, when light having a wavelength of about 450 nm to about 495 nm is generated in the emission layer 220 on the third pixel electrode 210B, the transmissive layer 730 may emit the light to the outside without wavelength conversion. In one or more embodiments, the transmissive layer 730 may include a third scatterer SC3 and a third base resin BR3. The third scatterer SC3 may be dispersed in the third base resin BR3. In one or more embodiments, the transmissive layer 730 may not include quantum dots.

At least one of the first quantum dot QD1 or the second quantum dot QD2 may include a semiconductor material, such as cadmium sulfide (CdS), cadmium telluride (CdTe), zinc sulfide (ZnS), and/or indium phosphide (InP). The quantum dot may have a size of several nanometers, and the wavelength of light after conversion may vary depending on the size of the quantum dot.

In one or more embodiments, the core of the quantum dot may be selected from a Group II-VI compound, a Group III-V compound, a Group IV-VI compound, a Group IV element, a Group IV compound, and/or a combination thereof.

The Group II-VI compound may be selected from among a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of AglnS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compound may be selected from among a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The Group IV-VI compound may be selected from among a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The Group IV element may be selected from the group consisting of Si, Ge, and a mixture thereof. The Group IV group compound may be a binary compound selected from the group consisting of SiC, SiGe, and a mixture thereof.

In this case, the binary compound, ternary compound, or quaternary compound may exist in a particle at a uniform concentration, or may exist in the same particle by being divided into states between which the concentration distribution is partially different. In addition, the quantum dot may have a core/shell structure in which one quantum dot surrounds another quantum dot. The interface between the core and the shell may have a concentration gradient in which the concentration of an element present in the shell decreases toward the center.

In one or more embodiments, the quantum dot may have a core-shell structure including a core including nanocrystals and a shell surrounding the core. The shell of the quantum dot may function as a protective layer to prevent chemical modification of the core and maintain semiconductor properties and/or as a charging layer to impart electrophoretic properties to the quantum dot. The shell may include a single layer or a multilayer. The interface between the core and the shell may have a concentration gradient in which the concentration of the element present in the shell decreases toward the center. Examples of the shell of the quantum dot may include a metal or non-metal oxide, a semiconductor compound, and/or a combination thereof.

For example, the metal or non-metal oxide may be a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound, such as MgAl₂O₄, CoFe₂O₄, NiFe₂O₄, and/or CoMn₂O₄. However, the present disclosure is not limited thereto.

In addition, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb. However, the present disclosure is not limited thereto.

In addition, the shape of the quantum dot is not particularly limited to a shape commonly used in the art, but more specifically, a shape such as a spherical, pyramidal, multi-arm, and/or cubic nanoparticle, nanotube, nanowire, nanofiber, and/or nanoplate particle may be used.

The quantum dot may control the color of emitted light depending on the particle size thereof, and accordingly, the quantum dot may have various emission colors, such as blue, red, and green.

The first scatterer SC1, the second scatterer SC2, and the third scatterer SC3 may scatter light so that more light may be emitted. The first scatterer SC1, the second scatterer SC2, and the third scatterer SC3 may increase light emission efficiency. At least one of the first scatterer SC1, the second scatterer SC2, or the third scatterer SC3 may be a material from among metals or metal oxides for evenly scattering light. For example, at least one of the first scatterer SC1, the second scatterer SC2, or the third scatterer SC3 may be TiO₂, ZrO₂, Al₂O₃, In₂O₃, ZnO, SnO₂, Sb₂O₃, and/or ITO. In addition, at least one of the first scatterer SC1, the second scatterer SC2, or the third scatterer SC3 may have a refractive index of about 1.5 or more. Accordingly, the light emission efficiency of the functional layer 700 may be improved. In one or more embodiments, at least one of the first scatterer SC1, the second scatterer SC2, or the third scatterer SC3 may be omitted.

The first base resin BR1, the second base resin BR2, and the third base resin BR3 may each include a light-transmitting material. For example, at least one of the first base resin BR1, the second base resin BR2, or the third base resin BR3 may include a polymer resin, such as acrylic, BCB, and/or HMDSO.

The second capping layer CL2 may be arranged on the lower surface of the light conversion portion LC. That is, the second capping layer CL2 may be arranged on the bank layer 600 and the functional layer 700. The second capping layer CL2 may protect the bank layer 600 and the functional layer 700. The second capping layer CL2 may prevent or reduce damage and/or contamination of the bank layer 600 and/or the functional layer 700 by impurities, such as moisture and/or air, penetrating from the outside. The second capping layer CL2 may include an inorganic material.

The display apparatus 1 as described above may emit light of a second wavelength band to the outside from the first pixel PX1, emit light of a third wavelength band to the outside from the second pixel PX2, and emit light of a first wavelength band to the outside from the third pixel PX3. That is, the display apparatus 1 may display a full-color image.

In one or more embodiments, a filling layer 30 may be arranged between a light-emitting panel or the lower panel 10 and a color panel or the upper panel 20. The filling layer 30 may be arranged between the encapsulation layer 300 and the second capping layer CL2 on the bank layer 600 and the functional layer 700. The filling layer 30 may function as a buffer against external pressure, etc. The filling layer 30 may include a filler. In one or more embodiments, the filling layer 30 may include a thermosetting and/or photocurable filler. The filler may be made of an organic material, such as methyl silicone, phenyl silicone, and/or polyimide. However, the present disclosure is not limited thereto, and the filler may include an organic sealant, such as a urethane-based resin, an epoxy-based resin, and/or an acrylic-based resin, an inorganic sealant, and/or silicone.

In one or more embodiments, one of the lower panel 10 and the upper panel 20 may include a column spacer CS. In one or more embodiments, the upper panel 20 may include the column spacer CS. In one or more other embodiments, the lower panel 10 may include the column spacer CS. Hereinafter, a detailed description will be given focusing on a case where the upper panel 20 includes the column spacer CS. In one or more embodiments, the column spacer CS may be arranged on the lower surface of the second capping layer CL2, which is below the bank layer 600 and the functional layer 700, and may face the first substrate 100. In one or more other embodiments, the column spacer CS may be arranged on the lower surface of the bank layer 600 and may face the first substrate 100. The column spacer CS may separate the encapsulation layer 300 from the bank layer 600. The column spacer CS may pass through the filling layer 30. The column spacer CS may include an organic material. In one or more embodiments, the column spacer CS may include an acrylic-based material.

The column spacer CS may separate the light-emitting element from the light conversion portion LC at a uniform interval. Therefore, the filling layer 30 may be arranged with a uniform thickness in the display area DA. In other words, the distance between the first organic light-emitting diode OLED1 and the first quantum dot layer 710 may be substantially the same as the distance between the second organic light-emitting diode OLED2 and the second quantum dot layer 720. In addition, the distance between the second organic light-emitting diode OLED2 and the second quantum dot layer 720 may be substantially the same as the distance between the third organic light-emitting diode OLED3 and the transmissive layer 730. However, in one or more embodiments, the column spacer CS may be omitted.

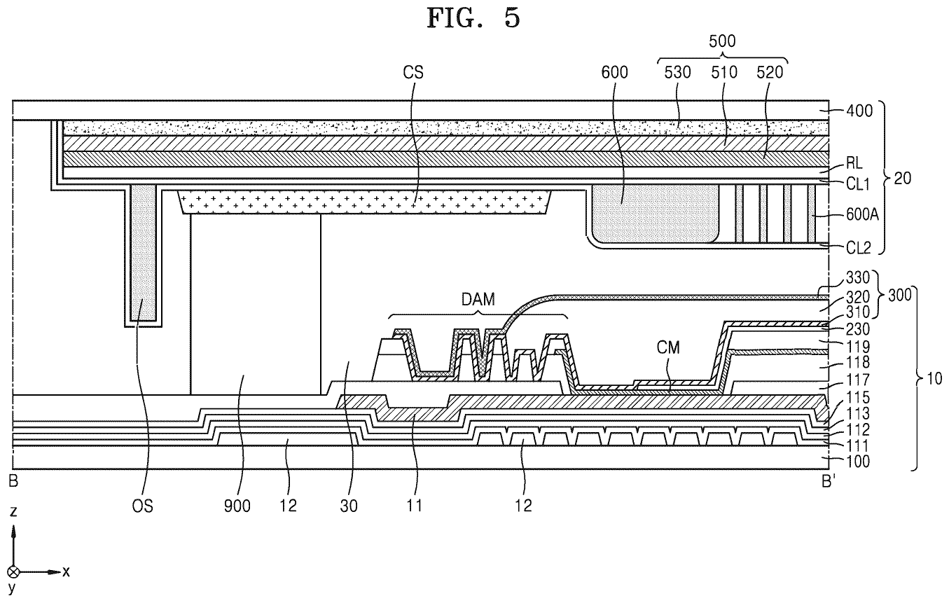

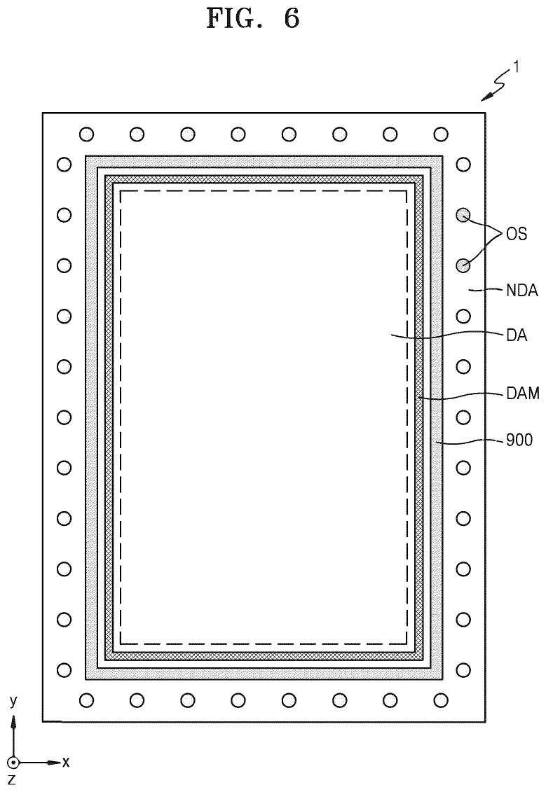

FIG. 5 is a cross-sectional view of the display apparatus 1 taken along the line B-B′ of FIG. 1. FIG. 6 is a schematic plan view of a display apparatus according to one or more embodiments.

Referring to FIGS. 5 and 6, the display apparatus 1 may include a dam portion DAM arranged on the edge of a first substrate 100. The dam portion DAM may be arranged on the periphery of the display area DA to define the boundary of an organic encapsulation layer 320 when the organic encapsulation layer 320 is formed. In this case, at least one dam portion DAM may be provided. For example, a plurality of dam portions DAM may be provided to be spaced (e.g., spaced apart) from each other from the end of the first substrate 100. The dam portion DAM may include an insulating layer. For example, the dam portion DAM may include the same layer as at least one of the planarization layer 118 or the pixel-defining layer 119. In addition, the dam portion DAM may also include the wiring protection layer 117. In one or more embodiments, the dam portion DAM may further include the same layer as a spacer arranged on the pixel-defining layer 119. In the case described above, when the dam portion DAM includes a plurality of layers, the height of one of the plurality of dam portions DAM may be different from the height of another one of the plurality of dam portions DAM. For example, the height of a dam portion DAM closer to the end of the first substrate 100 from among the plurality of dam portions DAM may be greater than the height of another one of the plurality of dam portions DAM.

The upper surface of at least one of dams forming the dam portion DAM may be in direct contact with the first inorganic encapsulation layer 310 or the second inorganic encapsulation layer 330. In one or more embodiments, in a plan view, the upper surface of at least one of the dams forming the dam portion DAM may not overlap the organic encapsulation layer 320. That is, the first inorganic encapsulation layer 310 and the second inorganic encapsulation layer 330 may form an inorganic contact area, and thus may block or reduce moisture and/or impurities from penetrating from the outer edge of a lower panel 10 to light-emitting elements arranged in the display area DA (see FIG. 4).

The display apparatus 1 may include a wiring portion 12 arranged between the first substrate 100 and the first buffer layer 111. In this case, the wiring portion 12 may include a fan-out line. In one or more embodiments, the wiring portion 12 may be arranged between the first buffer layer 111 and the second buffer layer 112 in addition to the above-described position. In one or more embodiments, some of a plurality of wiring portions 12 may be arranged between the first buffer layer 111 and the first substrate 100, and other ones of the plurality of wiring portions 12 may be arranged between the first buffer layer 111 and the second buffer layer 112.

The display apparatus 1 may include a driving voltage supply line 11. In this case, the driving voltage supply line 11 may extend to a non-display area NDA. The display apparatus 1 may include a connection wiring line CM connected to the driving voltage supply line 11. In this case, the connection wiring line CM may be connected to the driving voltage supply line 11, and an extending portion of the opposite electrode 230 may be arranged above the connection wiring line CM.

An upper panel 20 may include the color filter layer 500 extending to the non-display area NDA. The color filter layer 500 may include a first color filter 510, a second color filter 520, and a third color filter 530 that are stacked in the non-display area NDA. Because a plurality of color filters, that is, the first to third color filters 510, 520, and 530, overlap each other, light emitted from the lower panel 10 may not pass through the color filter layer 500. Accordingly, the non-display area NDA may be an area that is not visible.

In addition to the refractive layer RL, at least one of the first capping layer CL1 or the second capping layer CL2 may be arranged on the refractive layer RL on the color filter layer 500. That is, at least one of the first capping layer CL1 or the second capping layer CL2 may be arranged to extend from a portion of a second substrate 400 corresponding to the display area DA (see FIG. 4) of the lower panel 10 to the end of the second substrate 400, thereby shielding one side of the refractive layer RL. At least one of the first capping layer CL1 or the second capping layer CL2 may include an inorganic insulating material, such as silicon oxide (SiO₂), silicon nitride (SiN_{X}), and/or silicon oxynitride (SiON).

The bank layer 600 may be arranged between the first capping layer CL1 and the second capping layer CL2. The bank layer 600 may be arranged to overlap a portion of the non-display area NDA from the display area DA. The bank layer 600 may include a dummy bank layer 600A arranged in the non-display area NDA. In one or more embodiments, the dummy bank layer 600A may have additional openings that do not overlap the light-emitting elements in a plan view. A functional layer 700 (see FIG. 4) may be arranged in a plurality of openings of the dummy bank layer 600A. For example, a transmissive layer 730 (see FIG. 4) may be arranged in the plurality of openings of the dummy bank layer 600A

The bank layer 600 may include a black matrix material or a light-blocking material, such as a red pigment, a purple pigment, or a blue pigment. Alternatively, the bank layer 600 may include a metal oxide to increase the reflectivity on the surface thereof, thereby effectively preventing or reducing external light incident on the second substrate 400 from reaching a driving circuit, etc.

The column spacer CS may be additionally arranged on the lower surface of the second substrate 400. In one or more embodiments, the column spacer CS may be arranged on the lower surface of the color filter layer 500. In one or more embodiments, when the refractive layer RL is arranged on the lower surface of the color filter layer 500, the column spacer CS may be arranged on the lower surface of the refractive layer RL. In addition, as shown in FIG. 5, when at least one of the first capping layer CL1 or the second capping layer CL2 is arranged on the lower surface of the refractive layer RL in the non-display area NDA, the column spacer CS may be arranged on the lower surface of the capping layer (CL1 or CL2).

The column spacer CS may reduce deformation of the first substrate 100 and the second substrate 400 due to external pressure when the first substrate 100 and the second substrate 400 are bonded to each other, and may maintain a gap between the first substrate 100 and the second substrate 400. In one or more embodiments, the column spacer CS may include an organic material including an acrylic-based material. However, the present disclosure is not limited thereto, and in one or more other embodiments, the column spacer CS may include a polymer resin and a pigment or dye dispersed in the polymer resin. For example, the column spacer CS may include a light-blocking material, such as a black pigment, a dye, and/or carbon black.

The column spacer CS may extend in a first direction (e.g., the y direction) in the non-display area NDA. That is, the column spacer CS may be arranged to overlap a sealing member 900 in a second direction (e.g., the x direction) or a third direction (e.g., a z direction) in the non-display area NDA. Accordingly, the column spacer CS may support an outer area of the display apparatus 1 together with the sealing member 900, thereby effectively preventing deformation of the first substrate 100 and the second substrate 400.

The sealing member 900 may couple the first substrate 100 to the second substrate 400. In other words, the sealing member 900 may be arranged between the lower panel 10 and the upper panel 20. The sealing member 900 may be arranged in the non-display area NDA to be around (e.g., to surround) an outer area of the display area DA. For example, the sealing member 900 may have a shape of a hollow square in a plan view, as shown in FIG. 6. However, the shape of the sealing member 900 is not limited thereto. When the first substrate 100 and the second substrate 400 have various plane shapes, such as a triangle, a rhombus, a polygon, a circle, or an oval, the sealing member 900 may have a plane shape, such as a hollow triangle, a hollow rhombus, a hollow polygon, a hollow circle, or a hollow oval. In one or more embodiments, the sealing member 900 may include an organic material. For example, the sealing member 900 may include an epoxy resin. In one or more other embodiments, the sealing member 900 may be applied in the form of a frit including glass, etc.

In one or more embodiments, the filling layer 30 including a filler may be placed in a space between the lower panel 10 and the upper panel 20 surrounded by the sealing member 900. The filling layer 30 may fill the space between the lower panel 10 and the upper panel 20. The filler included in the filling layer 30 may include a material that may transmit light. For example, the filler may include an organic material including a silicon-based organic material, an epoxy-based organic material, or a mixture of a silicon-based organic material and an epoxy-based organic material.

In one or more embodiments, the upper panel 20 may further include an outer structure OS. The outer structure OS may be placed on the lower surface of the upper panel 20 and may be placed outside the sealing member 900. Specifically, in one or more embodiments, the outer structure OS may be placed on the lower surface of the color filter layer 500. In one or more embodiments, as shown in FIG. 5, when at least one of the first capping layer CL1 or the second capping layer CL2 is arranged on the lower surface of the refractive layer RL in the non-display area NDA, the outer structure OS may be interposed between the first capping layer CL1 and the second capping layer CL2. As shown in FIG. 6, the outer structure OS may have a dot shape in a plan view. A plurality of outer structures OS may be provided, and the plurality of outer structures OS may be spaced (e.g., spaced apart) from each other. The plurality of outer structures OS may be arranged to be around (e.g., to surround) the sealing member 900 in a plan view.

The outer structure OS may include the same material as the thickest layer from among the plurality of layers formed in the upper panel 20. However, based on a third direction (e.g., the z direction), the thickness of the outer structure OS may be less than the thickness of the sealing member 900. That is, the upper surface of the outer structure OS may contact the upper panel 20, but the lower surface of the outer structure OS may not contact the lower panel 10.

Specifically, the outer structure OS may include the same material as the bank layer 600 included in the light conversion portion LC (see FIG. 4). As the outer structure OS is formed through the same process as the bank layer 600, the outer structure OS may be arranged on substantially the same layer as the bank layer 600. Accordingly, the outer structure OS may be placed between the first capping layer CL1 and the second capping layer CL2.

The outer structure OS may be arranged on the lower surface of the color filter layer 500 and the refractive layer RL formed on the lower surface of the second substrate 400. That is, the outer structure OS may be arranged to overlap the first color filter 510, the second color filter 520, the third color filter 530, and the refractive layer RL. In addition, as the outer structure OS is formed through the same process as the bank layer 600, the column spacer CS may be formed after the outer structure OS is formed. Accordingly, the outer structure OS may be arranged so as not to overlap the column spacer CS in a plan view. The outer structure OS may be arranged outside the column spacer CS.

Generally, while a plurality of layers are arranged in the display area DA, not many layers are arranged in the non-display area NDA, especially in the outer area of the sealing member 900, and thus, a step may occur between a central area and a border area of the display apparatus 1. In this case, when the lower panel 10 and the upper panel 20 are bonded to each other, the first substrate 100 and the second substrate 400 may be warped in the non-display area NDA, or cracks may occur due to excessive pressing between the panels.

However, in the case of the display apparatus according to one or more embodiments, when the outer structure OS is arranged outside the sealing member 900, the outer structure OS may function as a support to prevent excessive pressing during the process of bonding the lower panel 10 and the upper panel 20. Specifically, the outer structure OS may maintain the gap between the first substrate 100 and the second substrate 400 so that the gap between the first substrate 100 and the second substrate 400 does not become closer to the thickness of the outer structure OS at the outermost portion. Accordingly, the outer structure OS may reduce deformation of the first substrate 100 and the second substrate 400 due to external pressure. In addition, the outer structure OS may prevent or reduce defects, such as film separation or cracks that may occur during the bonding process. As a result, the display apparatus according to one or more embodiments may prevent moisture from penetrating through cracks from the outside by including the outer structure OS, and may improve the reliability and lifespan of the display apparatus.

In addition, as the outer structure OS is formed by using the thickest layer from among the plurality of layers arranged in the upper panel 20, an additional process for forming the outer structure OS may not be necessary. Accordingly, the outer structure OS may enable the bonding process to be efficiently performed while maintaining the simplification of the process.

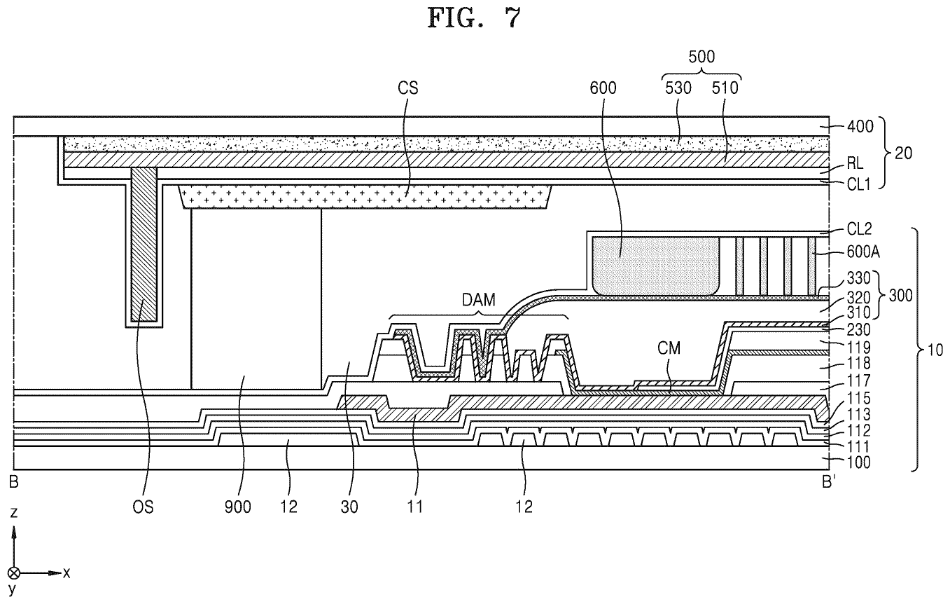

FIG. 7 is a schematic cross-sectional view of a display apparatus according to one or more embodiments. Referring to FIG. 7, except for the features of the outer structure OS and the bank layer 600, the other features are the same as those described with reference to FIGS. 5 and 6. In FIG. 7, the same reference numerals as those in FIGS. 5 and 6 denote the same members as those in FIGS. 5 and 6, and thus, the following description focuses on the differences.

Referring to FIG. 7, the upper panel 20 may include the color filter layer 500 extending into the non-display area NDA. In one or more embodiments, the color filter layer 500 arranged in the non-display area NDA may include only the first color filter 510 and the third color filter 530. That is, the second color filter 520 (see FIG. 4) may not be arranged in the non-display area NDA. As described above, the first color filter 510 may be a red color filter that may allow only light having a wavelength of about 630 nm to about 780 nm to pass through, the second color filter 520 (see FIG. 4) may be a green color filter that may allow only light having a wavelength of about 495 nm to about 570 nm to pass through, and the third color filter 530 may be a blue color filter that may allow only light having a wavelength of about 450 nm to about 495 nm to pass through. Accordingly, even when only the first color filter 510 and the third color filter 530 are arranged to overlap each other in the non-display area NDA, light emitted from the lower panel 10 may not pass through the color filter layer 500.

The refractive layer RL, the first capping layer CL1, and the column spacer CS may be arranged on the lower surface of the color filter layer 500. However, in one or more embodiments, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10. The lower panel 10 may include a light-emitting element, the encapsulation layer 300, and the light conversion portion LC (see FIG. 4) formed therein, the upper panel 20 may include the color filter layer 500, the refractive layer RL, the first capping layer CL1, and the column spacer CS formed therein, and the lower panel 10 and the upper panel 20 may be coupled to each other through the sealing member 900. In this case, because the second capping layer CL2 is intended to cover the light conversion portion LC (see FIG. 4), the second capping layer CL2 may also be formed in the lower panel 10. The second capping layer CL2 may be arranged on the upper surface of the bank layer 600.

The upper panel 20 may further include the outer structure OS. As described above, the outer structure OS may include the same material as the thickest layer from among a plurality of layers formed in the upper panel 20. In one or more embodiments, as shown in FIG. 7, when the bank layer 600 is formed in the lower panel 10, the outer structure OS may include the same material as the second color filter 520 (see FIG. 4) formed in the upper panel 20. That is, instead of arranging the second color filter 520 (see FIG. 4) to extend in the first direction (e.g., the y direction) in the non-display area NDA of the upper panel 20, the outer structure OS may be formed of the same material as the second color filter 520.

As the outer structure OS includes the same material as the second color filter 520 (see FIG. 4), the outer structure OS may be arranged on the lower surface of the first color filter 510. In addition, after the outer structure OS is formed, the refractive layer RL, the first capping layer CL1, and the column spacer CS may be formed. Accordingly, the first capping layer CL1 may be formed to cover the outer structure OS, and the outer structure OS may be arranged so as not to overlap the column spacer CS in a plan view. The outer structure OS may be arranged outside the column spacer CS and the sealing member 900.

In the case where the outer structure OS is formed of the same material as the second color filter 520 (see FIG. 4), as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the second color filter 520 (see FIG. 4) arranged in the display area DA is used, the simplification of the process may be maintained even in the display apparatus as shown in FIG. 7.

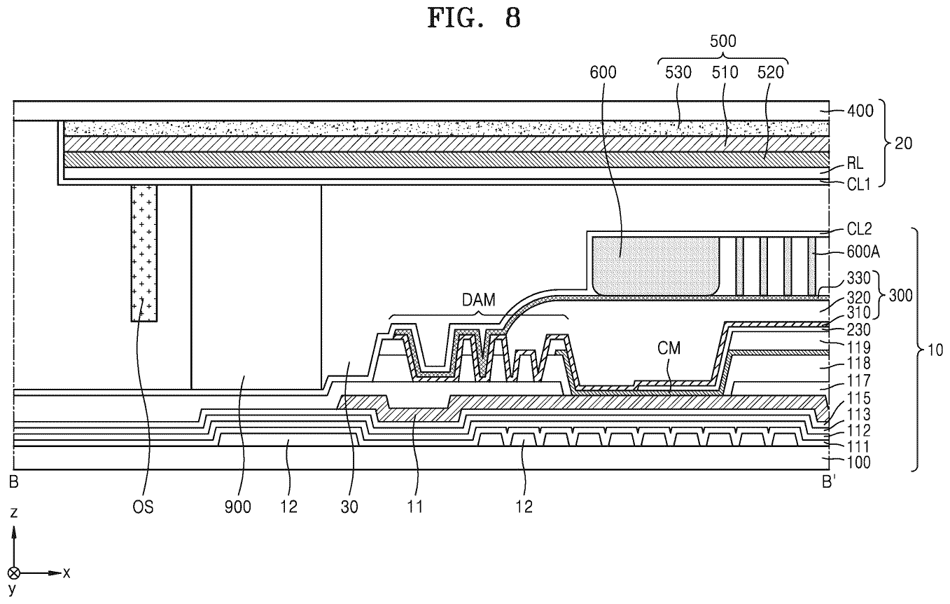

FIG. 8 is a schematic cross-sectional view of a display apparatus according to one or more embodiments. Referring to FIG. 8, except for the features of the outer structure OS and the bank layer 600, the other features are the same as those described with reference to FIGS. 5 and 6. In FIG. 8, the same reference numerals as those in FIGS. 5 and 6 denote the same members as those in FIGS. 5 and 6, and thus, the following description focuses on the differences.

Referring to FIG. 8, the upper panel 20 may include the color filter layer 500 extending into the non-display area NDA. The color filter layer 500 may include a first color filter 510, a second color filter 520, and a third color filter 530 that are stacked in the non-display area NDA. Because a plurality of color filters, that is, the first to third color filters 510, 520, and 530, overlap each other, light emitted from the lower panel 10 may not pass through the color filter layer 500. Accordingly, the non-display area NDA may be an area that is not visible.

The refractive layer RL and the first capping layer CL1 may be arranged on the lower surface of the color filter layer 500. However, in one or more embodiments, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10. For example, as shown in FIG. 8, the lower panel 10 may include a light-emitting element, an encapsulation layer 300, and a light conversion portion LC (see FIG. 4) formed therein, the upper panel 20 may include the color filter layer 500, the refractive layer RL, and the first capping layer CL1 formed therein, and the lower panel 10 and the upper panel 20 may be coupled to each other through a sealing member 900. In this case, because the second capping layer CL2 is intended to cover the light conversion portion LC (see FIG. 4), the second capping layer CL2 may also be formed in the lower panel 10. The second capping layer CL2 may be arranged on the upper surface of the bank layer 600.

The upper panel 20 may further include an outer structure OS. As described above, the outer structure OS may include the same material as the thickest layer from among a plurality of layers formed in the upper panel 20. In one or more embodiments, as shown in FIG. 8, when the bank layer 600 is formed in the lower panel 10, the outer structure OS may include the same material as the column spacer SC (see FIG. 4 and FIG. 5) formed in the upper panel 20. That is, instead of arranging the column spacer CS (see FIG. 4) to extend in the first direction (e.g., the y direction) in the non-display area NDA of the upper panel 20, the outer structure OS may be formed of the same material as the column spacer CS (see FIG. 4).

As the outer structure OS includes the same material as the column spacer CS (see FIG. 4), the outer structure OS may be arranged on the lower surface of the color filter layer 500, the refractive layer RL, and the first capping layer CL1. That is, one surface of the outer structure OS may be formed to be in contact with the first capping layer CL1. Because the column spacer CS (see FIG. 4) is not arranged and the outer structure OS is formed of the same material as the column spacer CS (see FIG. 4), the upper surface of the sealing member 900 may be in direct contact with the upper panel 20.

Similarly, in the case where the outer structure OS is formed of the same material as the column spacer CS (see FIG. 4), as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the column spacer CS (see FIG. 4) arranged in the display area DA is used, the simplification of the process may be maintained even in the display apparatus as shown in FIG. 8.

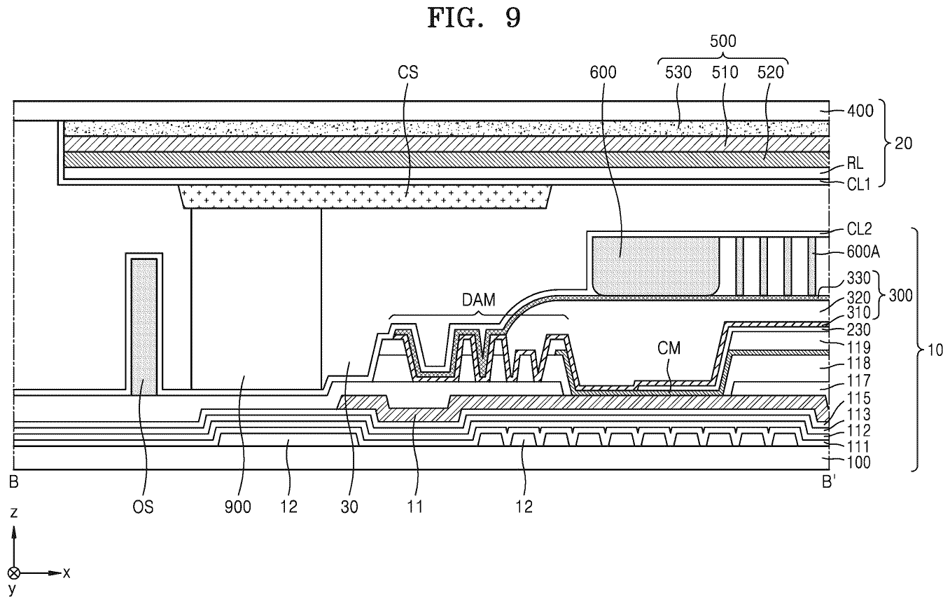

FIG. 9 is a schematic cross-sectional view of a display apparatus according to one or more embodiments. Referring to FIG. 9, except for the features of the outer structure OS and the bank layer 600, the other features are the same as those described with reference to FIGS. 5 and 6. In FIG. 9, the same reference numerals as those in FIGS. 5 and 6 denote the same members as those in FIGS. 5 and 6, and thus, the following description focuses on the differences.

Referring to FIG. 9, the upper panel 20 may include the color filter layer 500 extending into the non-display area NDA. The color filter layer 500 may include a first color filter 510, a second color filter 520, and a third color filter 530 that are stacked in the non-display area NDA.

The refractive layer RL, the first capping layer CL1, and the column spacer CS may be arranged on the lower surface of the color filter layer 500. However, in one or more embodiments, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10. The lower panel 10 may include a light-emitting element, an encapsulation layer 300, and a light conversion portion LC (see FIG. 4) formed therein, the upper panel 20 may include the color filter layer 500, the refractive layer RL, the first capping layer CL1, and the column spacer CS formed therein, and the lower panel 10 and the upper panel 20 may be coupled to each other through a sealing member 900. In this case, because the second capping layer CL2 is intended to cover the light conversion portion LC (see FIG. 4), the second capping layer CL2 may also be formed in the lower panel 10. The second capping layer CL2 may be arranged on the upper surface of the bank layer 600.

In one or more embodiments, the lower panel 10 may further include an outer structure OS. The outer structure OS may be arranged on the upper surface of the lower panel 10 and may be arranged outside the sealing member 900. The outer structure OS may include the same material as the thickest layer from among a plurality of layers formed in the lower panel 10. However, based on the third direction (e.g., the z direction), the thickness of the outer structure OS may be less than the thickness of the sealing member 900. That is, the lower surface of the outer structure OS may contact the lower panel 10, but the upper surface of the outer structure OS may not contact the upper panel 20.

Specifically, the outer structure OS may include the same material as the bank layer 600 included in the light conversion portion LC (see FIG. 4). As the outer structure OS is formed through the same process as the bank layer 600, the outer structure OS may be arranged on substantially the same layer as the bank layer 600. Accordingly, the upper surface of the outer structure OS may be covered by the second capping layer CL2. However, because the outer structure OS is arranged on the outer side of the sealing member 900, the outer structure OS may be formed on a wiring protection layer 117.

Similarly, in the case where the outer structure OS is formed in the lower panel 10, as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the bank layer 600 formed in the lower panel 10 is used, the process simplification may be maintained even in the display apparatus as shown in FIG. 9.

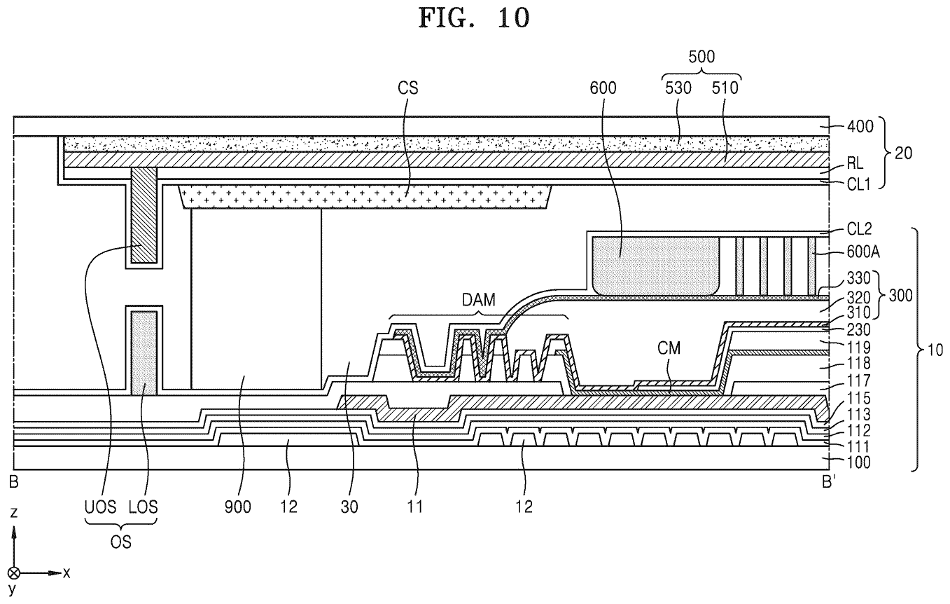

FIG. 10 is a schematic cross-sectional view of a display apparatus according to one or more embodiments. Referring to FIG. 10, except for the features of the outer structure OS, the other features are the same as those described with reference to FIG. 7. In FIG. 10, the same reference numerals as those in FIG. 7 denote the same members as those in FIG. 7, and thus, the following description focuses on the differences.

Referring to FIG. 10, the upper panel 20 may include the color filter layer 500 extending into the non-display area NDA. In one or more embodiments, the color filter layer 500 arranged in the non-display area NDA may include only a first color filter 510 and a third color filter 530. That is, the second color filter 520 (see FIG. 4) may not be arranged in the non-display area NDA.

In addition, the refractive layer RL, the first capping layer CL1, and the column spacer CS may be arranged on the lower surface of the color filter layer 500. However, in one or more embodiments, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10.

The outer structure OS may be formed in each of the lower panel 10 and the upper panel 20. Specifically, the outer structure OS may include a lower outer structure LOS formed in the lower panel 10 and an upper outer structure UOS formed in the upper panel 20. Specifically, the upper outer structure UOS may be arranged on the lower surface of the color filter layer 500, and the lower outer structure LOS may be arranged on the upper surface of the wiring protection layer 117.

Even in the case of the above structure, the upper outer structure UOS may include the same material as the thickest layer from among a plurality of layers formed in the upper panel 20, and the lower outer structure LOS may include the same material as the thickest layer from among a plurality of layers formed in the lower panel 10.

In one or more embodiments, the upper outer structure UOS may include the same material as the second color filter 520 (see FIG. 4) formed in the upper panel 20. That is, instead of arranging the second color filter 520 (see FIG. 4) to extend in the first direction (e.g., the y direction) in the non-display area NDA of the upper panel 20, the upper outer structure UOS may be formed of the same material as the second color filter 520. The lower outer structure LOS may include the same material as the bank layer 600 included in the light conversion portion LC (see FIG. 4). As the upper outer structure UOS is formed through the same process as the second color filter 520 (see FIG. 4), the upper outer structure UOS may be arranged on substantially the same layer as the second color filter 520 (see FIG. 4). As the lower outer structure LOS is formed through the same process as the bank layer 600, the lower outer structure LOS may be arranged on substantially the same layer as the bank layer 600.

Similarly, in the case where the outer structure OS is formed in each of the lower panel 10 and the upper panel 20, as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the bank layer 600 formed in the lower panel 10 and the second color filter 520 (see FIG. 4) formed in the upper panel (20) are used, the process simplification may be maintained even in the display apparatus as shown in FIG. 10.

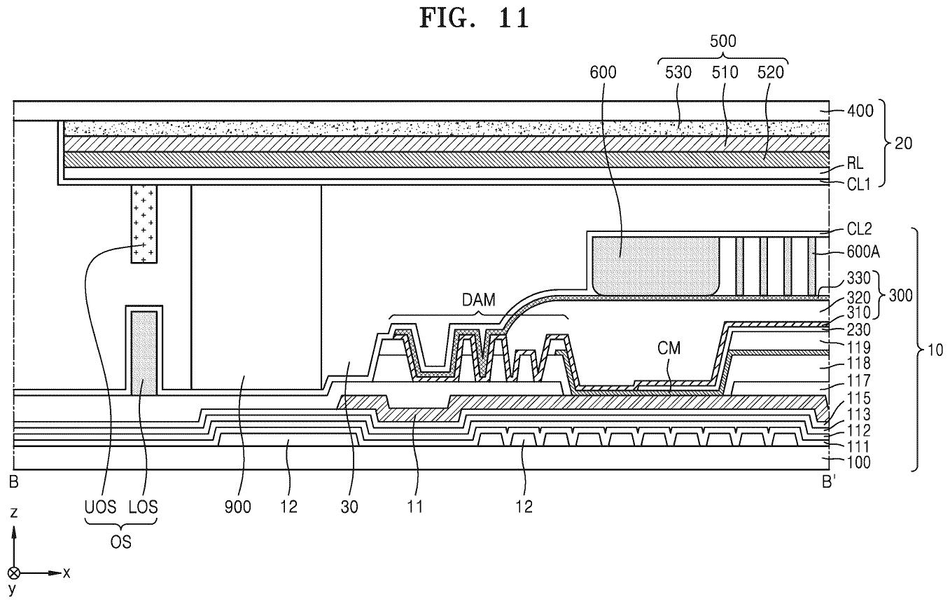

FIG. 11 is a schematic cross-sectional view of a display apparatus according to one or more embodiments. Referring to FIG. 11, except for the features of the outer structure OS, the other features are the same as those described with reference to FIG. 8. In FIG. 11, the same reference numerals as those in FIG. 8 denote the same members as those in FIG. 8, and thus, the following description focuses on the differences.

Referring to FIG. 11, the upper panel 20 may include the color filter layer 500 extending into the non-display area NDA. The color filter layer 500 may include a first color filter 510, a second color filter 520, and a third color filter 530 that are stacked in the non-display area NDA.

The refractive layer RL and the first capping layer CL1 may be arranged on the lower surface of the color filter layer 500. However, in one or more embodiments, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10.

The outer structure OS may be formed in each of the lower panel 10 and the upper panel 20. Specifically, the outer structure OS may include a lower outer structure LOS formed in the lower panel 10 and an upper outer structure UOS formed in the upper panel 20. Specifically, the upper outer structure UOS may be arranged on the lower surface of the color filter layer 500 (e.g., lower surface of the first capping layer CL1), and the lower outer structure LOS may be arranged on the upper surface of the wiring protection layer 117.

Even in the case of the above structure, the upper outer structure UOS may include the same material as the thickest layer from among a plurality of layers formed in the upper panel 20, and the lower outer structure LOS may include the same material as the thickest layer from among a plurality of layers formed in the lower panel 10.

In one or more embodiments, the upper outer structure UOS may include the same material as the column spacer CS (see FIG. 4) formed in the upper panel 20. That is, instead of arranging the column spacer CS (see FIG. 4) to extend in the first direction (e.g., the y direction) in the non-display area NDA of the upper panel 20, the upper outer structure UOS may be formed of the same material as the column spacer CS (see FIG. 4). The lower outer structure LOS may include the same material as the bank layer 600 included in the light conversion portion LC (see FIG. 4). As the upper outer structure UOS is formed through the same process as the column spacer CS (see FIG. 4), the upper outer structure UOS may be arranged on substantially the same layer as the column spacer CS (see FIG. 4). As the lower outer structure LOS is formed through the same process as the bank layer 600, the lower outer structure LOS may be arranged on substantially the same layer as the bank layer 600.

Similarly, in the case where the outer structure OS is formed in each of the lower panel 10 and the upper panel 20, as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the bank layer 600 formed in the lower panel 10 and the column spacer CS (see FIG. 4) formed in the upper panel 20 are used, the process simplification may be maintained even in the display apparatus as shown in FIG. 11.

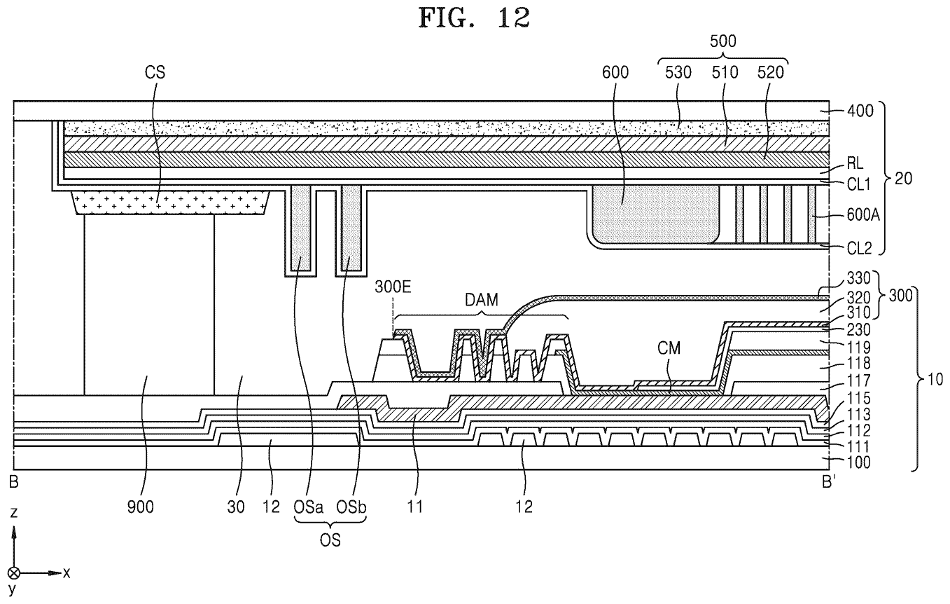

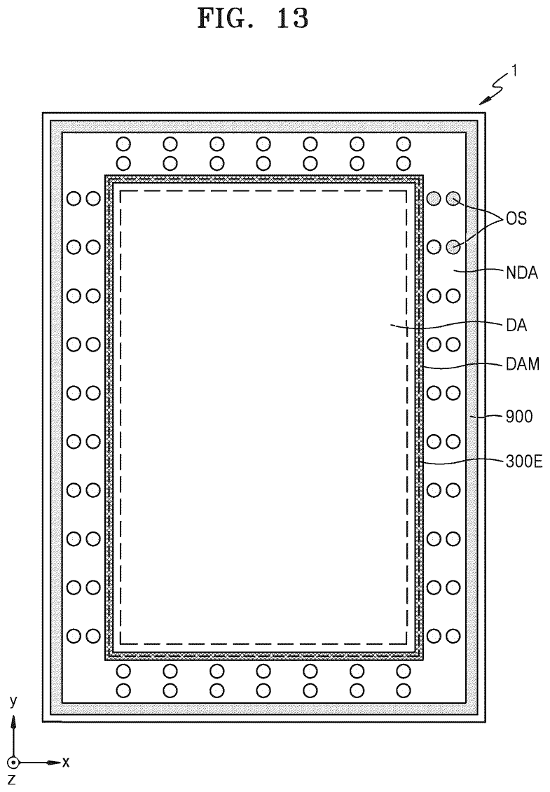

FIG. 12 is a schematic cross-sectional view of a display apparatus according to one or more embodiments. FIG. 13 is a schematic plan view of a display apparatus according to one or more embodiments. Referring to FIGS. 12 and 13, except for the features of the outer structure OS, the other features are the same as those described with reference to FIGS. 5 and 6. In FIGS. 12 and 13, the same reference numerals as those in FIGS. 5 and 6 denote the same members as those in FIGS. 5 and 6, and thus, the following description focuses on the differences.

Referring to FIG. 12, in one or more embodiments, the upper panel 20 may further include an outer structure OS. The outer structure OS may be arranged on the lower surface of the upper panel 20 and may be arranged outside an end 300E of the encapsulation layer 300. Specifically, the outer structure OS may be arranged between the end 300E of the encapsulation layer 300 and the sealing member 900. The outer structure OS may be arranged on the lower surface of the color filter layer 500 (e.g., may be arranged on the lower surface of the first capping layer CL1 and may be interposed between the first capping layer CL1 and the second capping layer CL2).

In one or more embodiments, the outer structure OS may include a first sub-outer structure OSa and a second sub-outer structure OSb that are spaced (e.g., spaced apart) from each other. The first sub-outer structure OSa may be arranged relatively outside the second sub-outer structure OSb. That is, the first sub-outer structure OSa may be arranged closer to the sealing member 900 than the second sub-outer structure OSb, and the second sub-outer structure OSb may be arranged closer to the end of the encapsulation layer 300 than the first sub-outer structure OSa.

As shown in FIG. 13, the outer structure OS may have a dot shape in a plan view. A plurality of outer structures OS may be provided, and the plurality of outer structures OS may be spaced (e.g., spaced apart) from each other. The plurality of outer structures OS may be arranged to be around (e.g., may surround) the end 300E of the encapsulation layer 300 in a plan view. In addition, the plurality of outer structures OS may be arranged to be surrounded by the sealing member 900 in a plan view. As shown in FIG. 12 and FIG. 13, when the outer structure OS has the first sub-outer structure OSa and the second sub-outer structure OSb, multiple layers of outer structures OS may be arranged to be around (e.g., to surround) the end 300E of the encapsulation layer 300 in a plan view.

The first sub-outer structure OSa and the second sub-outer structure OSb may each include the same material as the thickest layer from among a plurality of layers formed in the upper panel 20. However, based on the third direction (e.g., the z direction), the thickness of the outer structure OS may be less than the thickness of the sealing member 900. Specifically, the first sub-outer structure OSa and the second sub-outer structure OSb may each include the same material as the bank layer 600 included in the light conversion portion LC (see FIG. 4). As the first sub-outer structure OSa and the second sub-outer structure OSb are formed through the same process as the bank layer 600, the first sub-outer structure OSa and the second sub-outer structure OSb may be arranged on substantially the same layer as the bank layer 600 (e.g., lower surface of the first capping layer CL1 and may be interposed between the first capping layer CL1 and the second capping layer CL2).

The outer structure OS may be arranged on the lower surface of the color filter layer 500 and the refractive layer RL formed on the lower surface of the second substrate 400. That is, the outer structure OS may be arranged to overlap the first color filter 510, the second color filter 520, the third color filter 530, and the refractive layer RL. In addition, as the outer structure OS is formed through the same process as the bank layer 600, the column spacer CS may be formed after the outer structure OS is formed. Accordingly, the outer structure OS may be arranged so as not to overlap the column spacer CS in a plan view. The outer structure OS may be arranged inside the column spacer CS.

Similarly, in the case where the outer structure OS is formed between the end 300E of the encapsulation layer 300 and the sealing member 900, as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. In particular, when the outer structure OS is formed as a double structure including the first sub-outer structure OSa and the second sub-outer structure OSb, the outer structure OS may more effectively prevent deformation of the lower panel 10 and the upper panel 20. As a result, the display apparatus according to one or more embodiments may prevent moisture from penetrating from the outside by including the outer structure OS, and may improve the reliability and lifespan of the display apparatus.

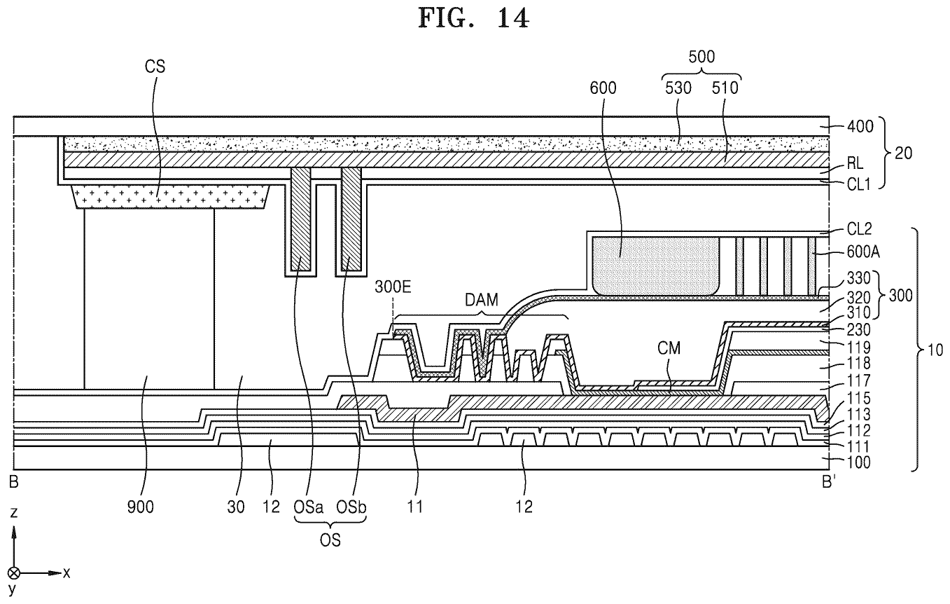

FIG. 14 is a schematic cross-sectional view of a display apparatus according to one or more embodiments. Referring to FIG. 14, except for the features of the outer structure OS and the bank layer 600, the other features are the same as those described with reference to FIG. 13. In FIG. 14, the same reference numerals as those in FIG. 13 denote the same members as those in FIG. 13, and thus, the following description focuses on the differences.

Referring to FIG. 14, the upper panel 20 may include the color filter layer 500 extending into the non-display area NDA. In an embodiment, the color filter layer 500 arranged in the non-display area NDA may include only a first color filter 510 and a third color filter 530. That is, the second color filter 520 (see FIG. 4) may not be arranged in the non-display area NDA. As described above, the first color filter 510 may be a red color filter that may allow only light having a wavelength of about 630 nm to about 780 nm to pass through, the second color filter 520 (see FIG. 4) may be a green color filter that may allow only light having a wavelength of about 495 nm to about 570 nm to pass through, and the third color filter 530 may be a blue color filter that may allow only light having a wavelength of about 450 nm to about 495 nm to pass through. Accordingly, even when only the first color filter 510 and the third color filter 530 are arranged to overlap each other in the non-display area NDA, light emitted from the lower panel 10 may not pass through the color filter layer 500.

The refractive layer RL, the first capping layer CL1, and the column spacer CS may be arranged on the lower surface of the color filter layer 500. However, in an embodiment, the bank layer 600 may not be arranged on the lower surface of the color filter layer 500, but may be arranged on the upper surface of the encapsulation layer 300. In other words, the bank layer 600 may not be included in the upper panel 20, but may be included in the lower panel 10. The lower panel 10 may include a light-emitting element, an encapsulation layer 300, and a light conversion portion LC (see FIG. 4) formed therein, the upper panel 20 may include the color filter layer 500, the refractive layer RL, and the column spacer CS formed therein, and the lower panel 10 and the upper panel 20 may be coupled to each other through a sealing member 900. In this case, because the second capping layer CL2 is intended to cover the light conversion portion LC (see FIG. 4), the second capping layer CL2 may also be formed in the lower panel 10. The second capping layer CL2 may be arranged on the upper surface of the bank layer 600.

The upper panel 20 may further include an outer structure OS. The outer structure OS may be arranged between the end 300E of the encapsulation layer 300 and the sealing member 900. As described above, the outer structure OS may include the same material as the thickest layer from among a plurality of layers formed in the upper panel 20. In one or more embodiments, as shown in FIG. 14, when the bank layer 600 is formed in the lower panel 10, the outer structure OS may include the same material as the second color filter 520 (see FIG. 4) formed in the upper panel 20. That is, instead of arranging the second color filter 520 (see FIG. 5) to extend in the first direction (e.g., the y direction) in the non-display area NDA of the upper panel 20, the outer structure OS may be formed of the same material as the second color filter 520 (see FIG. 5).

As the outer structure OS includes the same material as the second color filter 520 (see FIG. 4), the outer structure OS may be arranged on the lower surface of the first color filter 510. In addition, after the outer structure OS is formed, the refractive layer RL, the first capping layer CL1, and the column spacer CS may be formed. Accordingly, the first capping layer CL1 may be formed to cover the outer structure OS, and the outer structure OS may be arranged so as not to overlap the column spacer CS in a plan view. The outer structure OS may be arranged inside the column spacer CS and the sealing member 900.

Similarly, in the case where the outer structure OS is formed of the same material as the second color filter 520 (see FIG. 4), as in the display apparatus according to one or more embodiments, the outer structure OS may function as a support so that excessive pressing does not occur during the process of bonding the lower panel 10 to the upper panel 20. The outer structure OS may maintain a gap between the first substrate 100 and the second substrate 400, thereby reducing deformation of the first substrate 100 and the second substrate 400 due to external pressure, and may prevent cracks, etc. that may occur on the upper surface of the sealing member 900. As a result, the display apparatus according to one or more embodiments may prevent moisture from penetrating from the outside by including the outer structure OS, and may improve the reliability and lifespan of the display apparatus. In addition, because the second color filter 520 (see FIG. 4) arranged in the display area DA is used, the simplification of the process may be maintained even in the display apparatus as shown in FIG. 14.

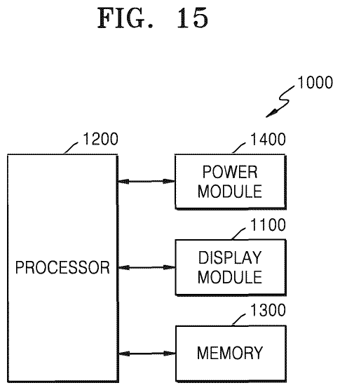

FIG. 15 is a block diagram of an electronic device 1000 according to one or more embodiments.

Referring to FIG. 15, the electronic device 1000 according to one or more embodiments may include a display module 1100, a processor 1200, a memory 1300, and a power module 1400.

The electronic device 1000 may output various pieces of information through the display module 1100 within an operating system.

The processor 1200 may include at least one of a central processing unit (CPU), an application processor (AP), a graphic processing unit (GPU), a communication processor (CP), an image signal processor (ISP), or a controller. In one or more embodiments, the processor 1200 may be provided by being functionally or structurally divided into two or more processors. For example, the processor 1200 may include a main processor in the form of a first driving chip including a CPU, and an auxiliary processor in the form of a second driving chip including a controller configured to receive an image signal from the main processor and process the image signal to be adapted to an interface specification of the display module 1100.

The memory 1300 may include at least one of a non-volatile memory or a volatile memory. The memory 1300 may store data information required for an operation of the processor 1200 or the display module 1100. When the processor 1200 executes an application stored in the memory 1300, an image data signal and/or an input control signal may be transmitted to the display module 1100, and the display module 1100 may process the provided signal, and thus, may output image information via a display screen.

The power module 1400 may include a power supply module such as a power adaptor or a battery device, and a power conversion module for generating, by converting power supplied by the power supply module, power required for an operation of the electronic device 1000. Power conversion by the power conversion module may include, but is not limited to, direct current (DC)-DC conversion, alternating current (AC)-DC conversion, and/or DC-AC conversion.

At least one of the components of the electronic device 1000 described above may be included in the display apparatus according to the embodiments described above. In addition, some of individual modules functionally included in one module may be included in the display apparatus, and others may be provided separately from the display apparatus. For example, the display apparatus may include the display module 1100 and an auxiliary processor of the processor 1200, and a main processor of the processor 1200), the memory 1300, and the power module 1400 may be provided in the form of other devices in the electronic device 1100 other than the display apparatus. As another example, the power module 1400 may be arranged in the display apparatus and may supply power to the processor 1200 and the memory 1300 arranged in the electronic device 1100 other than the display apparatus. However, the present disclosure is not limited thereto.

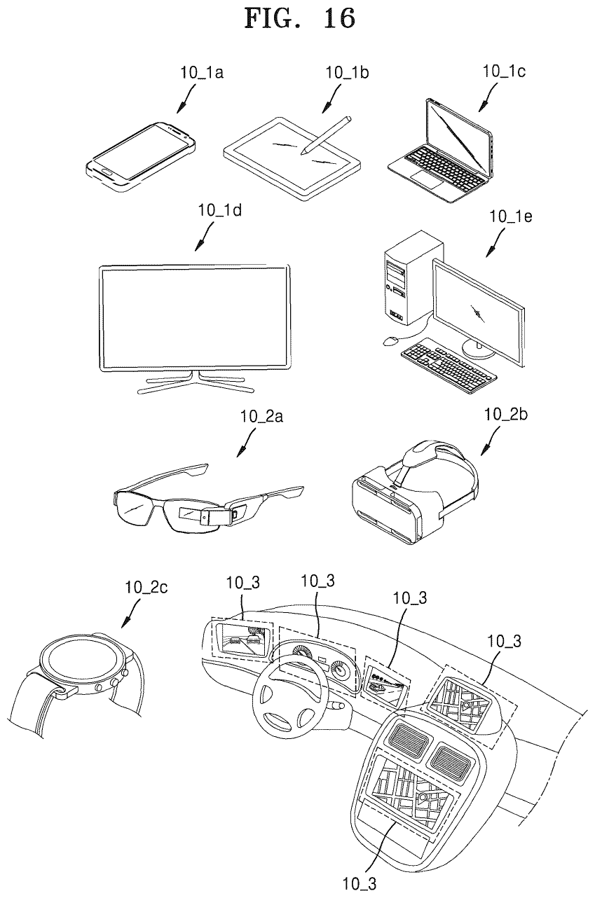

FIG. 16 is a schematic diagram of electronic devices according to one or more embodiments.

The display apparatus according to one or more embodiments is a device that displays a moving image and/or a still image, and may be applied to various electronic devices. Referring to FIG. 16, various electronic devices to which the display apparatus according to one or more embodiments is applied may each include not only an image display electronic device, such as a smartphone 10_1a, a tablet PC 10_1b, a laptop 10_1c, a television (TV) 10_1d, or a desk monitor 10_1e, but also a wearable electronic device including a display module, such as smart glasses 10_2a, a head mounted display 10_2b, or a smart watch 10_2c, and a vehicle electronic device 10_3 including a display module, such as a Center Information Display (CID) and/or a room mirror display, placed on a panel, center fascia, and/or dashboard of a car. The electronic device 1000 according to one or more embodiments is not limited to the aforementioned devices.

The electronic devices of FIG. 16 may include the components illustrated in FIG. 15. For example, the smartphone 10_1a may include the display module 1100, the processor 1200, the memory 1300, and the power module 1400, illustrated in FIG. 15. The smartphone 10_1a may further include a communication module and a battery device. Power provided from the battery device may be converted through the power module 1400 and provided to the processor 1200, the memory 1300, and the display module 1100. In one or more embodiments, a display apparatus applied to the smartphone 10_1a may include the display module 1100 and further include the power module 1400. The processor 1200 and the memory 1300 may be provided in the form of chips mounted on a motherboard, which is an external device, but are not limited thereto.

According to one or more embodiments, a display apparatus having increased reliability and lifespan and an electronic device including the display apparatus may be provided. The aforementioned effects, aspects, and features are shown as examples, and the effect, aspects, and features of the present disclosure are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various changes in form and details may be made therein without departing from the spirit and scope as defined by the following claims and their equivalents.

What is claimed is:

1. A display apparatus comprising:
a lower panel including a display area and a non-display area outside the display area, the lower panel comprising a light-emitting element in the display area and an encapsulation layer covering the light-emitting element;
an upper panel on the lower panel;
a sealing member in the non-display area and located between the lower panel and the upper panel; and
an outer structure in at least one of the lower panel or the upper panel and located outside an end of the encapsulation layer.

2. The display apparatus of claim 1, wherein a thickness of the outer structure is less than a thickness of the sealing member based on a direction perpendicular to the lower panel.

3. The display apparatus of claim 1, wherein the outer structure has a dot shape in a plan view.

4. The display apparatus of claim 1, wherein the outer structure is located outside the sealing member.

5. The display apparatus of claim 4, wherein the outer structure comprises a plurality of outer structures, the plurality of outer structures being spaced from each other and being around the sealing member in a plan view.

6. The display apparatus of claim 1, wherein the outer structure is located between the end of the encapsulation layer and the sealing member.

7. The display apparatus of claim 6, wherein the outer structure comprises a first sub-outer structure and a second sub-outer structure that are spaced from each other,
wherein the first sub-outer structure is located outside the second sub-outer structure.

8. The display apparatus of claim 1, wherein the outer structure is located in the upper panel and comprises a same material as a thickest layer from among a plurality of layers located in the upper panel.

9. The display apparatus of claim 1, wherein the upper panel further comprises a light conversion portion that is configured to convert light emitted from the light-emitting element, and the outer structure comprises a same material as a bank layer in the light conversion portion.

10. The display apparatus of claim 9, wherein the upper panel further comprises:
an upper substrate;
a color filter layer located on a lower surface of the upper substrate in the non-display area; and
a column spacer on a lower surface of the color filter layer in the non-display area,
wherein the outer structure is on the lower surface of the color filter layer and is located outside the column spacer.

11. The display apparatus of claim 1, wherein the outer structure comprises a same material as a green color filter located in the upper panel.

12. The display apparatus of claim 11, wherein the lower panel further comprises a light conversion portion located between the light-emitting element and the upper panel.

13. The display apparatus of claim 1, wherein the outer structure comprises a same material as a column spacer located in the upper panel,

14. The display apparatus of claim 13, wherein the lower panel further includes a light conversion portion arranged between the light-emitting element and the upper panel.

15. The display apparatus of claim 1, wherein the outer structure is arranged in the lower panel and includes a same material as a thickest layer among a plurality of layers arranged in the lower panel.

16. The display apparatus of claim 15, wherein the lower panel further includes a light conversion portion that converts light emitted from the light-emitting element, and the outer structure includes a same material as a bank layer included in the light conversion portion.

17. The display apparatus of claim 1, wherein the outer structure includes:
a lower outer structure arranged in the lower panel; and
an upper outer structure arranged in the upper panel.

18. The display apparatus of claim 17, wherein the lower panel further includes a light conversion portion that converts light emitted from the light-emitting element, and the outer structure includes a same material as a bank layer included in the light conversion portion.

19. The display apparatus of claim 17, wherein the upper outer structure includes a same material as a column spacer or a green color filter arranged in the upper panel.

20. An electronic device comprising:
a display apparatus configured to display an image; and
a housing in which the display apparatus is located,
wherein the display apparatus comprises:
a lower panel including a display area and a non-display area outside the display area, the lower panel comprising a light-emitting element located in the display area and an encapsulation layer covering the light-emitting element;
an upper panel on the lower panel;
a sealing member in the non-display area and located between the lower panel and the upper panel; and
an outer structure in at least one of the lower panel or the upper panel and located outside an end of the encapsulation layer.
